(19) United States
(12) Patent Application Publication
(10) Pub. No.: US 2026/0005054 A1
(43) Pub. Date: Jan. 1, 2026

(54) MOBILE SENSOR DEVICES FOR SEMICONDUCTOR FABRICATION EQUIPMENT

(71) Applicant: Lam Research Corporation, Fremont, CA (US)

(72) Inventors: Travis R. Taylor, Portland, OR (US); Todd A. Lopes, Livermore, CA (US); Pratik Vijay Yadav, Fremont, CA (US); Christopher William Burkhart, Los Gatos, CA (US)

(21) Appl. No.: 18/881,353

(22) PCT Filed: Jun. 26, 2023
(86) PCT No.: PCT/US2023/026181

§ 371 Date: Jan. 6, 2025

Related U.S. Application Data
(60) Provisional application No. 63/368,041, filed on Jul. 8, 2022.

(51) Int. Cl. H01L 21/68; B25J 9/16; H01L 21/677; H01L 21/687

(52) U.S. Cl. CPC H01L 21/681; B25J 9/1697; H01L 21/677; H01L 21/68707

(57) ABSTRACT

Systems and techniques for obtaining various types of sensor information regarding operational aspects of a semiconductor processing tool are disclosed. Such systems and techniques may involve an instrumented wafer that includes one or more different types of sensors, including, for example, pressure sensors, oxygen (or other gas) sensors, humidity sensors, upward- and/or outward-facing imaging sensors or optical sensors, microphone sensors, and so forth.

### RELATED APPLICATION(S)

An Application Data Sheet is filed concurrently with this specification as part of the present application. Each application that the present application claims benefit of or priority to as identified in the concurrently filed Application Data Sheet is incorporated by reference herein in its entirety and for all purposes.

### BACKGROUND

At various points in time, semiconductor equipment may need to be calibrated or inspected to optimize processing conditions and/or check one or more aspects of the equipment's condition. In some cases, semiconductor equipment manufacturers and operators have used wafers that are instrumented with accelerometers and downward-facing cameras to assist with wafer movement characterization and wafer centering or calibration operations. Such wafers, for example, are discussed in patent publication no. WO2021022291, titled “INTEGRATED ADAPTIVE POSITIONING SYSTEMS AND ROUTINES FOR AUTOMATED WAFER-HANDLING ROBOT TEACH AND HEALTH CHECK,” the content of which is hereby incorporated herein by reference in its entirety.

### SUMMARY

Details of one or more implementations of the subject matter described in this specification are set forth in the accompanying drawings and the description below. Other features, aspects, and advantages will become apparent from the description, the drawings, and the claims. The following, non-limiting implementations are considered part of the disclosure; other implementations will be evident from the entirety of this disclosure and the accompanying drawings as well.

In some implementations, a device for evaluating characteristics of a semiconductor processing tool or component may be provided. Such a device may include a base structure sized so as to be insertable through an opening of the semiconductor processing tool sized to receive wafers for processing and transportable by an object transfer apparatus of the semiconductor processing tool between at least two locations in the semiconductor processing tool. The base structure may have a first side configured to contact, and be supported by, a portion of the object transfer apparatus and a second side facing in a direction opposite the first side. The device may further include one or more optical sensors, each optical sensor oriented so as to have an upward-facing field of view when the base structure is oriented with the first side facing downward, a controller communicatively connected with each of the one or more optical sensors, and a power source configured to provide power to at least the controller.

In some implementations, at least one of the one or more optical sensors may be an imaging sensor.

In some implementations, at least one of the one or more optical sensors may be coupled with a corresponding one or more lenses that provide that optical sensor with a field of view of at least 30°.

In some implementations, the device may have two or more optical sensors, and the two or more optical sensors may be distributed across the device so as to have overlapping fields of view with respect to a focal plane parallel to, and located a first distance from, the second side.

In some such implementations, the first distance may be between 2 mm and 100 mm.

In some implementations, a region resulting from an intersection of the focal plane with the fields of view of the optical sensors may have a total area that is at least 15% of πd²/4, where d is a nominal wafer diameter of wafers that the semiconductor processing tool is configured to process.

In some implementations, there may be a plurality of optical sensors and at least two of the optical sensors may be located at different distances from a center point of the base structure.

In some implementations, the device may further include a first support structure rotatably coupled with the base structure. The device may also further include a first rotational drive configured to cause the first support structure to rotate about a first rotational axis and relative to the base structure responsive to receipt of one or more first control signals. At least one of the one or more optical sensors may be supported, directly or indirectly, by the first support structure and may be located at a distance offset from the first rotational axis in a direction perpendicular to the first rotational axis.

In some implementations, there may be multiple optical sensors that are supported, directly or indirectly, by the first support structure and at least two of the optical sensors supported by the first support structure may be located at different distances from the first rotational axis.

In some implementations, the first rotational axis may be nominally centered on the base structure.

In some implementations, the first rotational axis may be offset from a center of the base structure.

In some implementations, the device may further include a second support structure that is rotatably coupled with the first support structure. The device may also further include a second rotational drive configured to cause the second support structure to rotate about a second rotational axis and relative to the first support structure responsive to receipt of one or more second control signals. The second support structure may be supported by the first support structure, the at least one of the one or more optical sensors may be supported by the second support structure, and the second rotational axis may be offset radially from the first rotational axis.

In some implementations, the base structure may have a maximum dimension that is 50% or less of a nominal wafer diameter of wafers that the semiconductor processing tool is configured to process.

In some implementations, the base structure may have a maximum dimension that is 50% or less of 300 mm, and at least one of the one or more optical sensors may be positioned at a location on the base structure that is offset from a center axis of the base structure that is perpendicular to the second side.

In some implementations, there may be a plurality of optical sensors and one of the optical sensors may be located proximate the center axis of the base structure.

In some implementations, the device may further include a first optical projection unit configured to project a first illumination pattern along a first axis. In such an implementation, the first axis may be at an oblique angle to the second side, the first axis may intersect with a reference plane that is parallel to, and offset a first distance from, the second side, the first side may be farther from the reference plane than the second side, and the one or more optical sensors may be positioned such that at least some locations where the reference plane and the first illumination pattern may intersect are within an aggregate field of view of the one or more optical sensors.

In some such implementations, the first illumination pattern may intersect the reference plane along a first line.

In some implementations, the device may further include a second optical projection unit. In such implementations, the second optical projection unit may be configured to project a second illumination pattern along a second reference plane that is perpendicular to the second side and parallel to the first line along which the first illumination pattern intersects the reference plane, and the second illumination pattern may intersect the reference plane along a second line that is parallel to the first line.

In some implementations, the first illumination pattern may intersect the reference plane at a plurality of discrete locations distributed across the reference plane.

In some implementations, a device for evaluating characteristics of a semiconductor processing tool or component may be provided. The device may include a base structure sized so as to be insertable through an opening of the semiconductor processing tool sized to receive wafers for processing and transportable by an object transfer apparatus of the semiconductor processing tool between at least two locations in the semiconductor processing tool, the base structure having a first side configured to contact, and be supported by, a portion of the object transfer apparatus and a second side facing in a direction opposite the first side. The device may also include one or more optical sensors, each optical sensor oriented so as to have a field of view that faces outward with respect to a center axis of the base structure. The device may also include a controller that is communicatively connected with each of the one or more optical sensors, and a power source configured to provide power to at least the controller.

In some implementations, there may be a plurality of optical sensors and the optical sensors may be located proximate an outer edge of the base structure.

In some implementations, the optical sensors may be arranged in a circular array.

In some implementations, the fields of view of the optical sensors may circumferentially overlap at a radial distance from the center axis of the base structure, and the radial distance may be equal to a distance from the center of a pedestal of the semiconductor processing tool and an interior wall surface of a semiconductor processing chamber of the semiconductor processing tool.

In some implementations, the device may further include a support structure rotatably coupled with the base structure. The device may also include a rotational drive configured to cause the support structure to rotate about a rotational axis responsive to receipt of one or more control signals, and at least one of the one or more optical sensors may be supported on the support structure.

In some implementations, the one or more optical sensors may be imaging sensors.

In some implementations, a device for evaluating characteristics of a semiconductor processing tool or component may be provided. The device may include a base structure sized so as to be insertable through a door of the semiconductor processing tool and transportable by an object transfer apparatus of the semiconductor processing tool between at least two locations in the semiconductor processing tool, the base structure having a first side configured to contact, and be supported by, a portion of the object transfer apparatus and a second side facing in a direction opposite the first side. The device may also include one or more first ambient atmospheric sensors supported by the base structure, each first ambient atmospheric sensor configured to measure a partial pressure of a first component of a target gas, a concentration of the first component in the target gas, a flow velocity of the target gas, or any combination of two or more thereof, wherein the first component of the target gas is not water. The device may also include a first controller. The first controller may be communicatively connected with each of the one or more first ambient atmospheric sensors and may be supported by the base structure. The device may also include a power source configured to provide power to at least the first controller.

In some implementations, the one or more first ambient atmospheric sensors may include at least one first ambient atmospheric sensor configured to measure the partial pressure of the first component in the target gas.

In some implementations, the one or more first ambient atmospheric sensors may include at least one first ambient atmospheric sensor configured to measure the concentration of the first component in the target gas.

In some implementations, the one or more first ambient atmospheric sensors may include at least one first ambient atmospheric sensor configured to measure the partial pressure of the first component and to also measure a partial pressure of a second component in the target gas different from the first component.

In some implementations, the first component may be oxygen and the second component may be water.

In some implementations, the first component may be oxygen.

In some implementations, a system may be provided that includes one of the devices described above. Such a system may include a semiconductor processing tool having one or more wafer-handling robots and a semiconductor processing chamber. The system may also include a second controller, the second controller communicatively coupled with the one or more wafer-handling robots. The base structure may further support a first wireless communications interface, the second controller may be communicatively coupled with a second wireless communications interface, the second controller may be configured to communicate with the first controller via a wireless communications link using the first wireless communications interface and the second wireless communications interface, and the second controller may be configured to cause the one or more wafer-handling robots to place the base structure into the semiconductor processing chamber and to send one or more commands to the first controller to cause the first controller to cause sensor readings to be obtained from the one or more first ambient atmospheric sensors while the base structure is within the semiconductor processing chamber.

In some implementations, the second controller may be further configured to cause a door of the semiconductor processing chamber to be sealed while the base structure is within the semiconductor processing chamber.

In some implementations, the second controller may be further configured to control one or more valves so as to cause any flows of gas into the semiconductor processing chamber via the one or more valves to be turned off at least while the sensor readings are being obtained.

In some implementations, the second controller may be further configured to control one or more vacuum pumps or one or more vacuum valves so as to cause any flow of gas from the semiconductor processing chamber to cease at least while the sensor reading are being obtained.

In some implementations, there may be a plurality of first ambient atmospheric sensors at spaced-apart locations on the base structure, the first controller or the second controller may be configured to identify a localized peak measurement of concentration or partial pressure of the first component of the target gas in the sensor readings, and the first controller or the second controller may be configured to determine which of the first ambient atmospheric sensors is associated with the localized peak measurement and to determine a probable leak location in the semiconductor processing chamber based on a location of the first ambient atmospheric sensor associated with the localized peak measurement relative to the semiconductor processing chamber.

In some implementations, the one or more first ambient atmospheric sensors may include at least one sensor configured to measure the flow velocity of the target gas.

In some implementations, the at least one sensor configured to measure the flow velocity of the target gas may be an anemometer.

In some implementations, the at least one sensor configured to measure the flow velocity of the target gas may be a hot-wire anemometer.

In some implementations, the at least one sensor configured to measure the flow velocity of the target gas may be a plurality of sensors configured to measure the flow velocity of the target gas.

In some implementations, the base structure may be circular and may have a diameter sized to match a diameter of a wafer that the semiconductor processing tool is configured to process, and two or more of the sensors configured to measure the flow velocity of the target gas may be arranged at locations proximate an outer edge of the base structure.

In some such implementations, the two or more sensors configured to measure the flow velocity of the target gas may be located at evenly spaced-apart locations along the outer edge of the base structure.

In some implementations, there may be at least first, second, and third sensors configured to measure the flow velocity of the target gas and the first, second, and third sensors configured to measure the flow velocity of the target gas may be spaced apart at 120° intervals.

In some implementations, there may be at least first, second, third, and fourth sensors configured to measure the flow velocity of the target gas and the first, second, third, and fourth sensors configured to measure the flow velocity of the target gas may be spaced apart at 90° intervals.

In some implementations, there may be one or more second ambient atmospheric sensors, each second ambient atmospheric sensor configured to measure a partial pressure of a first component of a target gas, a concentration of the first component in the target gas, or both.

In some implementations, the first component may be oxygen.

In some implementations, a system may be provided that includes a device as described above. The system may further include a semiconductor processing tool having an equipment front end module (EFEM) and one or more wafer-handling robots located within the EFEM. The system may further include a second controller, the second controller communicatively coupled with the one or more wafer-handling robots. The base structure may further support a first wireless communications interface, the second controller may be communicatively coupled with a second wireless communications interface, the second controller may be configured to communicate with the first controller via a wireless communications link using the first wireless communications interface and the second wireless communications interface, and the second controller may be configured to cause the one or more wafer-handling robots to move the base structure between a plurality of measurement locations and to send one or more commands to the first controller to cause the first controller to cause sensor readings to be obtained from the one or more first ambient atmospheric sensors in association with each measurement location and stored on one or more memory devices.

In some implementations, the semiconductor processing tool may further include a wafer buffer station located within the EFEM or connected with the EFEM, the wafer buffer station may have a plurality of wafer storage positions, and the plurality of measurement locations may include one or more measurement locations that coincide with one or more corresponding wafer storage positions.

In some implementations, the plurality of measurement locations may include one or more measurement locations within an interior of the EFEM.

In some implementations, the semiconductor processing tool may further include a load port configured to receive a front-opening unified pod (FOUP) and the plurality of measurement locations may include one or more measurement locations that coincide with a location within the FOUP when the FOUP is loaded on the load port.

In some implementations, a device for evaluating characteristics of a semiconductor processing tool or component may be provided. The device may include a base structure sized so as to be insertable through a door of the semiconductor processing tool and transportable by an object transfer apparatus of the semiconductor processing tool between at least two locations in the semiconductor processing tool, the base structure having a first side configured to contact, and be supported by, a portion of the object transfer apparatus and a second side facing in a direction opposite the first side. The device may further include one or more sound sensors supported by the base structure, a controller, wherein the controller is communicatively connected with each of the one or more sound sensors and is supported by the base structure; and a power source configured to provide power to at least the controller.

In some implementations, the one or more sound sensors may be a plurality of microphone sensors positioned in different locations on the base structure.

In some implementations, the microphone sensors in the plurality of microphone sensors may be arranged in a circular array on the base structure.

In some implementations, the one or more microphone sensors may be omnidirectional microphone sensors.

In some implementations, the one or more microphone sensors may be directional microphone sensors.

In some implementations, the device may further include a support structure that is rotatably coupled to the base structure. The device may also include a rotational drive configured to cause the support structure to rotate about a rotational axis responsive to receipt of one or more control signals, wherein at least one of the one or more microphone sensors is a directional microphone sensor and supported by the support structure.

In some implementations, a device for evaluating characteristics of a semiconductor processing tool or component may be provided. The device may include a base structure sized so as to be insertable through a door of the semiconductor processing tool and transportable by an object transfer apparatus of the semiconductor processing tool between at least two locations in the semiconductor processing tool, the base structure having a first side configured to contact, and be supported by, a portion of the object transfer apparatus and a second side facing in a direction opposite the first side. The device may also include a plurality of different types of sensors supported by the base structure, the types of sensors including sensors configured to detect acoustic signals, sensors configured to detect optical phenomena, sensors configured to measure flow velocity of a gas, and/or sensors configured to detect a concentration of a gas. The device may also include a power source configured to provide power to at least the controller.

In some implementations, the device may further include an inductive charging coil coupled to the power source.

### BRIEF DESCRIPTION OF THE DRAWINGS

The various implementations disclosed herein are illustrated by way of example, and not by way of limitation, in the figures of the accompanying drawings, in which like reference numerals refer to similar elements.

FIG. 1 depicts a schematic of a sensor-equipped wafer.

FIG. 2 depicts an example layout of optical sensors for an example sensor-equipped wafer.

FIG. 3 depicts an example of another layout of optical sensors for an example sensor-equipped wafer.

FIG. 4 depicts an example of another layout of optical sensors for an example sensor-equipped wafer.

FIG. 5 depicts the example sensor-equipped wafer of FIG. 4 in different rotational positions.

FIGS. 6-1 through 6-6 depict different stages of operation of a wafer handling robot and sensor-equipped wafer.

FIG. 7 depicts an example sensor-equipped wafer in which upward-facing optical sensors are mounted on a rotatable support structure.

FIGS. 8-11 show diagrams of an example smaller-diameter sensor-equipped wafer during various use phases.

FIG. 12 depicts the example sensor-equipped wafer of FIG. 2 but with illumination devices additionally included.

FIG. 13 depicts the example sensor-equipped wafer of FIG. 4 but with illumination devices additionally included.

FIG. 14 depicts an example sensor-equipped wafer with an illumination pattern projection system.

FIG. 15 depicts the example sensor-equipped wafer of FIG. 14 with an illumination pattern projection system in use with a showerhead that has a non-planar underside.

FIG. 16 depicts a variant of the sensor-equipped wafer of FIGS. 14 and 15 with a second illumination device configured to project a reference illumination pattern.

FIG. 17 depicts an example of a sensor-equipped wafer with optical sensors that are configured to have radially outward-facing fields of view.

FIG. 18 depicts an example of a sensor-equipped wafer with an optical sensor configured to have a radially outward-facing field of view mounted to a rotatable support structure.

FIGS. 19A and 19B depict another example sensor-equipped wafer in which upward-facing optical sensors are mounted on a rotatable support structure.

FIG. 20 depicts an example sensor-equipped wafer in which upward-facing optical sensors are mounted on a rotatable support structure that is, in turn, mounted to another rotatable support structure.

FIGS. 21A through 21E depict views of a sensor-equipped wafer with multiple different sets of optical sensors.

FIGS. 22A through 22C depict views of a sensor-equipped wafer with a steerable optical sensor.

FIG. 23 depicts an example of a sensor-equipped wafer that has a substrate that supports a plurality of ambient atmospheric sensors.

FIG. 24 depicts the same example sensor-equipped wafer of FIG. 23 but with differently-shaded regions representing different partial pressures resulting from a leak.

FIG. 25 depicts an example semiconductor processing tool (or a portion thereof) that may be configured to utilize a sensor-equipped wafer.

FIG. 26 depicts a schematic of a portion of a semiconductor processing tool.

FIG. 27 depicts an example of a sensor-equipped wafer that has a substrate that supports a plurality of microphone sensors.

FIG. 28 depicts an example of a sensor-equipped wafer that has a substrate that supports a plurality of directional microphone sensors.

FIG. 29 depicts an example of a sensor-equipped wafer that has a substrate that supports a rotatable support structure supporting a directional microphone sensor.

The Figures herein are generally not drawn to scale unless indicated as being drawn to scale below.

### DETAILED DESCRIPTION

The present inventors conceived of a number of different types of sensor-equipped wafers or substrates that may be used to evaluate various aspects of a semiconductor processing tool's operational capability and/or performance. It will be understood that, in many cases, features of the various implementations discussed may be implemented in tandem with features of other implementations discussed herein, e.g., on a single wafer or substrate. It will be readily understood that since many of the implementations discussed herein may utilize relatively small sensors (compared to the size of the wafer on which the sensors are supported), it is feasible to include multiple different sensors systems on a common wafer or substrate. For the purposes of this disclosure, reference to a wafer, in the context of a structure to which sensors discussed herein may be mounted, will be understood to refer to a wafer or substrate, and the two terms may be used interchangeably herein. More generally, the sensors and associated hardware (e.g., controller, power supply, memory, etc. that may be interfaced with such sensors) that are discussed below with reference to sensor-equipped wafers may also be mounted to structures other than a wafer or substrate, e.g., to a sheet or plate of material, e.g., composite or carbon fiber. The shape of the structure (also referred to herein as a “base structure”) to which such sensors and attendant hardware are mounted (either directly or indirectly) may be circular in shape, e.g., similar to a typical semiconductor wafer processed using semiconductor processing tools such as are discussed below, or may be other shapes, e.g., polygonal, oval, annular, square, triangular, etc. Some such structures may also be generally planar in nature, although other such structures may be non-planar in nature, e.g., slightly domed. It will be understood that for the purposes of this disclosure, reference to sensor-equipped wafers encompasses similar devices that are not necessarily limited to use of a wafer or substrate as the platform to which the sensors thereof, and the other hardware thereof, are attached (either directly or indirectly), such as devices that use structures such as, but not limited to, the examples provided above. Thus, reference to sensor-equipped wafers herein may be generally understood to also refer more generally to sensor-equipped devices. Similarly, references to a substrate of such a sensor-equipped wafer herein may be understood to also refer more generally to structures such as the above.

The sensor-equipped devices discussed herein may generally be designed so as to incorporate an independent power source, such as a rechargeable battery or other energy source. Such devices may also include one or more processors and one or more memory devices, as well as one or more communications interfaces, e.g., one or more wireless communications interfaces. The one or more processors may be configured, e.g., via instructions stored on the one or more memory devices, to obtain data from one or more sensors that may be operatively connected with the one or more processors and to store that data in the one or more memory devices for later communication to, for example, an external controller, e.g., a controller of a semiconductor processing tool. Such communication may, for example, be performed via a physical connection with the wafer (e.g., via a cable or connector) or via a wireless connection with the wafer, e.g., via Bluetooth or WiFi connection. It will be understood that this basic control and communications architecture may be used with a wide variety of different sensors and may be suitable for use in any of the examples discussed herein.

The sensor-equipped wafers discussed herein may also generally be designed to be transportable within a semiconductor processing tool and/or between semiconductor processing tools using the same equipment as is normally used to transport substrates or wafers during semiconductor processing operations. Thus, sensor-equipped wafers may generally be sized so as to be of a similar size and shape to substrates or wafers that would normally be processed using such equipment. For example, a sensor-equipped wafer for use with semiconductor processing tools used for 300 mm diameter wafer processing operations may be sized so as to be 300 mm in diameter and no more than, for example, 5 mm to 6 mm in maximum thickness. Such sensor-equipped wafers may thus be able to be transported by wafer-handling robots between at least two locations within a semiconductor processing tool, supported by shelves in buffers that may be dimensioned so as to contact the edges of wafers, loaded into and transported by front-opening unified pods (FOUPs), transported through slit valve apertures, wafer transfer passages, or other relatively wide, thin apertures that may be provided to allow wafers or substrates to be introduced into, or removed from, a semiconductor processing chamber and/or a semiconductor processing tool. In some implementations, the substrate used in a sensor-equipped wafer may, for example, be the same diameter as a semiconductor wafer that is typically processed within a semiconductor processing tool that the sensor-equipped wafer is configured to be used with. For example, if a semiconductor processing tool is configured to process 300 mm diameter wafers, the substrate of the sensor-equipped wafer may also be 300 mm in diameter. The thickness of such a substrate may, in some cases, be similar to the thickness of such a wafer, e.g., 0.75 mm to 1 mm. In other implementations, such a substrate may be larger and/or thicker than the wafers that are typically processed using the tool that the sensor-equipped wafer is intended to be used with, e.g., the substrate may be on the order of 2-4 mm thick or less and/or up to 400 mm in diameter for a tool that is designed to process 300 mm wafers, assuming that the tool has clearances that are sufficient to allow such an oversized wafer to still be able to be inserted into, and removed from, the processing chamber or chambers of such a tool in a manner similar to how a 300 mm wafer would be inserted into, and removed from, such a chamber or chambers. For example, some semiconductor processing tools may be designed to allow wafers to be moved into and out of the tool, and between locations within the tool, using a “carrier ring,” which are generally thin, annular structures having interior diameters that are nominally the same size as the diameter of the wafers they are designed to carry. Carrier rings may have a plurality of features that support a wafer from below, e.g., tabs that extend radially inward to locations within the wafer edge or may have a circumferential ledge along their inner circumference that is of a smaller diameter than the wafer diameter in order to be able to carry the wafer from location to location. In such systems, the semiconductor processing tool may have equipment that is configured to contact the carrier ring instead of the wafer directly. For example, lift pins or wafer handling robots may be configured and/or positioned so as to contact the carrier ring instead of the wafer. In some instances, carrier rings for a 300 mm diameter wafer may be as much as 25 mm thick and 400 mm in diameter; it will be understood that some implementations of sensor-equipped wafers as discussed herein may be therefore configured to have overall envelopes that are larger than discussed above, e.g., up to 400 mm in diameter and 25 mm thick (allowing for larger-thickness sensors to be used).

It will also be understood that a sensor-equipped wafer may, for example, also have an overall height (inclusive of the substrate and the components mounted thereto or supported thereby) that is thicker than the height of typical wafer that is processed. For example, if the clearances of the tool in which the sensor-equipped wafer is to be used support it, such a sensor-equipped wafer may have an overall thickness of up to 25 mm.

It will also be appreciated that sensor-equipped wafers such as those disclosed herein may also be sized large enough that they are not actually able to be inserted into, or withdrawn from, a semiconductor processing tool or chamber via an interface through which wafers to be processed are normally passed. For example, such an oversize sensor-equipped wafer may be provided to such a semiconductor processing tool or chamber through a larger, alternate interface from the interface through which the wafers to be processed are passed. In some cases, a top plate of a chamber or tool may be removed to allow a sensor-equipped wafer to be placed into the chamber or tool, or the chamber or tool may have a resting location or parking spot internal thereto that may house the sensor-equipped wafer when not in use, thereby allowing an over-sized sensor-equipped wafer to be usable without the need for inserting the sensor-equipped wafer into the chamber or tool prior to each use and then removing the sensor-equipped wafer from the chamber or tool after each use.

In some implementations discussed herein, one or more optical sensors, e.g., imaging sensors, photodetectors, etc., may be located on a side of a substrate that is configured to face upwards when placed in a semiconductor processing chamber. Such upward placement may allow the optical sensor(s) to obtain data regarding visible characteristics of, for example, a showerhead that is used to distribute gas across a wafer that may be loaded into the semiconductor processing chamber. Such data may, for example, provide insight as to one or more aspects of the condition that a portion of the semiconductor processing chamber is in. For example, the presence of deposited films on the underside of the showerhead or wear around gas distribution ports on the underside of the showerhead may be detectable using such data. A decision as to whether or not to clean and/or replace the showerhead may then be made based on the actual state of the showerhead as evidenced by such data. In cases in which the showerhead is, for example, experiencing a higher-than-expected rate of undesired deposition and/or wear on the underside thereof, such data may allow the operator of the semiconductor processing tool to potentially perform a cleaning or replacement operation on the showerhead earlier than would normally be scheduled (e.g., according to a typical replacement or cleaning schedule). In cases in which the showerhead is, for example, experiencing a lower-than-expected rate of undesired deposition and/or wear on the underside thereof, such data may allow the operator of the semiconductor processing tool to potentially delay a scheduled cleaning or replacement operation on the showerhead.

In some implementations discussed herein, one or more optical sensors may be positioned on a substrate so as to have a field of view that is directed along an axis that is parallel to, or at least somewhat parallel to, a substrate, e.g., such that the one or more optical sensors may be used to obtain data regarding visible characteristics of, for example, a side wall, slit valve, or other component or portion of a semiconductor processing chamber of a semiconductor processing tool when the substrate is positioned within the semiconductor processing chamber. Such an apparatus may, for example, be used to obtain data regarding visible characteristics of such components or portions of the semiconductor processing chamber, e.g., components or portions thereof that are positioned radially outward from where a semiconductor wafer would normally be located when subjected to semiconductor processing operations within the semiconductor processing chamber. Such data may allow a condition of such components or portions of the semiconductor processing chamber to be evaluated for potential undesired build-up (e.g., film build-up) and/or for potential wear or damage to components. This, in turn, may be used to determine if and/or when potential cleaning or component replacement operations may need to be scheduled.

In some implementations discussed herein, one or more humidity, gas level, temperature, and/or airflow velocity sensors may be located on a substrate that is configured to be placed within a semiconductor processing chamber. Such sensors may then be used to obtain measurement data relating to the ambient atmospheric conditions in the vicinity of the substrate. Measurement data from some such sensors may, for example, be used to evaluate the airflow across a substrate in various locations within an equipment front end module (EFEM), within a front-opening unified pod (FOUP), within a wafer buffer, within a load lock, or when being transported by a wafer handling robot within the EFEM. In other instances, measurement data from some such sensors may be used to determine levels of a particular type of gas, e.g., oxygen, that may exist in proximity to the substrate under vacuum or near-vacuum conditions within a semiconductor processing chamber. Such information may provide insight as to whether or not there are potential leaks of atmospheric air into the semiconductor processing chamber that exceed a particular limit. Such information may also be used in the context of a nitrogen-purged EFEM or other system that operates at atmospheric or near-atmospheric pressure but with an atmosphere that has a composition that is markedly different from normal atmospheric air, e.g., an atmosphere that is all-nitrogen (or nearly all nitrogen). In such cases, such data may provide insight as to what the actual composition of such an atmosphere is.

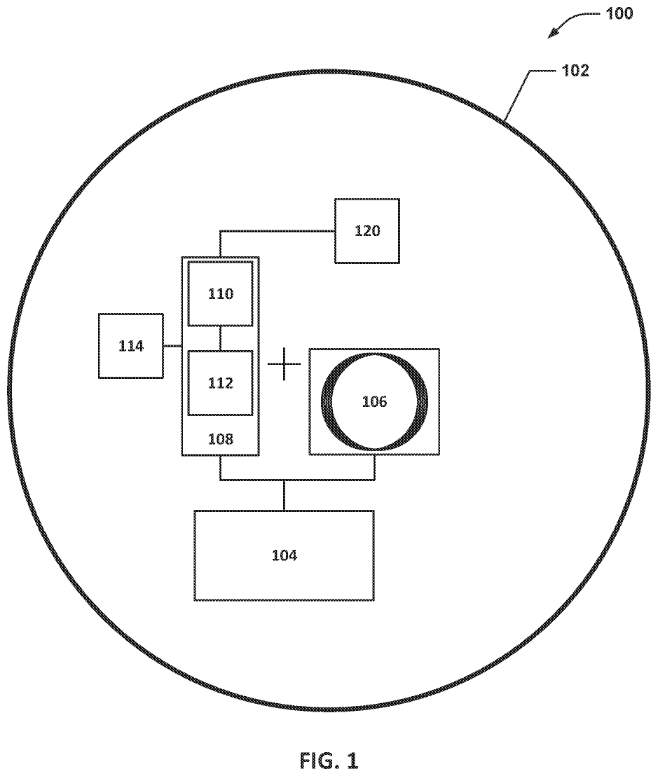

FIG. 1 depicts a schematic of an example sensor-equipped wafer 100 showing various example systems or components that may be included therein. As alluded to earlier, various sensors 120 included in the sensor-equipped wafer 100 may be communicatively connected with a first controller 108 that may include one or more first processors 110 and one or more first memories or memory devices 112. The first controller 108 may also be electrically connected with a power source 104, e.g., a battery, capattery, or other power source. In some implementations, the power source 104 may be operatively connected with a charging feature, e.g., with electrical contact pins that are placed in a location that aligns with charging features located at, for example, a docking station used to store the sensor-equipped wafer 100 when the sensor-equipped wafer 100 is placed into the docking station. In the implementation shown in FIG. 1, a wireless charging feature 106 is shown, which may, for example, be an inductive charging coil, such as a Qi-compatible inductive charging coil or other suitable wireless charging interface. In such cases, a docking station used to store the sensor-equipped wafer 100 may have a compatible wireless charging interface configured to charge the sensor-equipped wafer 100 when the sensor-equipped wafer 100 is placed therein. The various elements of the sensor-equipped wafer 100 may, as noted earlier, be mounted to or supported by a substrate 102.

The first controller 108 may also be communicatively connected with a first wireless communications interface 114, e.g., a WiFi, Bluetooth, or other wireless communications interface, so that commands and/or data may be sent from and/or to the first controller 108, and thus the sensor-equipped wafer 100. For example, a semiconductor processing tool that interfaces with the sensor-equipped wafer 100 may include a second controller having one or more second processors and one or more second memories. The second controller may be communicatively connected with a second wireless communications interface that may, in turn, be configured to interface with the first wireless communications interface 114 of the sensor-equipped wafer. Thus, the sensor-equipped wafer 100 may be able to wirelessly communicate with the semiconductor processing tool, allowing information, commands, and other data to be transmitted between the sensor-equipped wafer 100 and the semiconductor processing tool.

It will be appreciated that the basic architecture shown in FIG. 1, or other similar architectures, may be connected with one or more sensors 120. The one or more sensors 120 may, for example, include multiple sensors and may, in some implementations, include multiple sensors of multiple different types. It will be appreciated that the various components that are shown may be distributed so as to provide space for various individual sensors 120 as may be needed for a given layout or configuration of sensors.

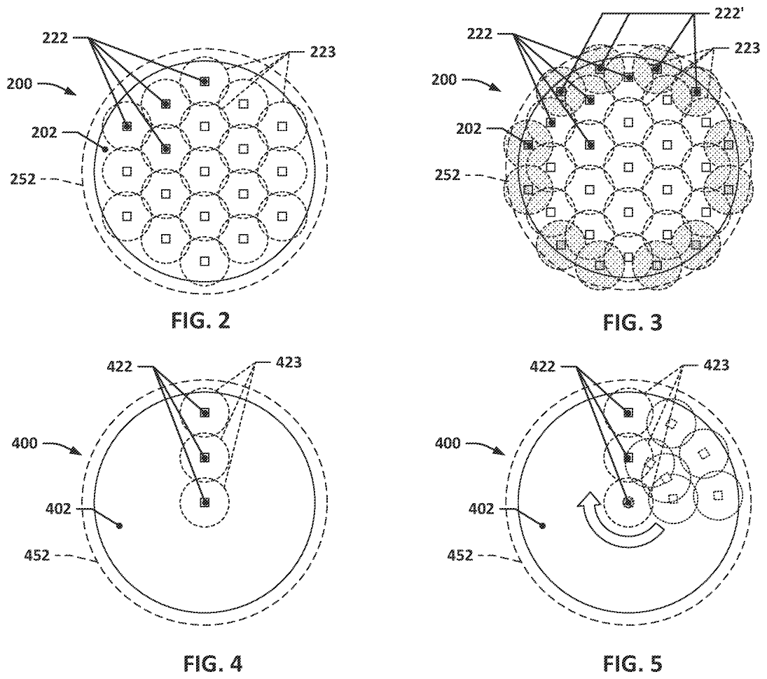

FIG. 2 depicts an example layout of optical sensors for an example sensor-equipped device or wafer, e.g., a layout for a group of sensors 120 of the sensor-equipped wafer 100. As can be seen in FIG. 2, a substrate 202 is provided; the substrate 202 may support various electronic systems, e.g., similar to the substrate 102, that may be used to provide control, power, and communications functionality for the plurality of sensors 120. The substrate 202 (and other substrates discussed herein) may generally be described as a nominally planar structure having a first side and a second side opposite the first side. The first side of the substrate 202 may, for example, be configured to rest on an end effector of a wafer-handling robot used to transport wafers in between locations within a semiconductor processing tool, while the second side may generally be oriented facing upwards during transport within the semiconductor processing tool. Alternatively, the first side of the substrate 202 may be configured to rest on some alternative type of object transfer system or apparatus of the semiconductor processing tool, e.g., on a rotational indexer, an autonomous robot that is able to freely navigate within a chamber or tool, etc. As can be seen in FIG. 2, optical sensors 222 (which are one example of sensors that may be included in the plurality of sensors 120) are distributed across an upper surface (the second side) of the substrate 202 such that each optical sensor 222 has a field of view that encompasses a region 223 on a reference plane that is offset upwards from, and in a direction perpendicular to, the substrate 202 by a distance X. The optical sensors 222 may thus have upward-facing fields of view when the sensor-equipped wafer is positioned such that the first side of the sensor-equipped wafer is facing downwards. When the substrate 202 is supported within a semiconductor processing chamber with the top surface of the substrate 202 facing upward and at the distance X from, for example, the underside of a showerhead (the outer perimeter of which is represented by a dashed circle 252 in FIG. 2) of the semiconductor processing chamber, a large portion of the underside of the showerhead 252 will be within the field of view of the optical sensors 222. The distance X may, in some implementations, be between 70 mm and 100 mm, e.g., between 80 mm and 90 mm, e.g., about 85 mm.

This arrangement may allow for the optical sensors 222 to obtain optical data regarding most of the underside of the showerhead 252. Thus, for example, if the optical sensors 222 are imaging sensors, e.g., digital cameras, the combined regions of the field of view on the reference plane may cover an area equal to 50%, 60%, 70%, 80%, or 90% or more (or even 100%) of the underside of the showerhead 252. In the event that the fields of view 223 of such imaging sensors overlap at a focal plane that is parallel to and at a first distance from the second side of the substrate 202, then the images obtained from these imaging sensors may be digitally composited to form a single, larger image of the focal plane. For example, if the focal plane is at the distance X, e.g., coincident with the underside of the showerhead, such a composite image may depict the entire underside, or nearly the entire underside, of the showerhead 252. Even if the fields of view 223 do not necessarily overlap in such a focal plane, the discrete images may still provide insight as to the condition of the showerhead 252.

In some implementations, multiple optical sensors 222 may be provided such that a region resulting from the intersection of the focal plane with the fields of view of the optical sensors 222 has a total area that is at least 15%, 20%, 30%, 40%, 50%, 60%, 70%, 80%, 90%, or 100% of the area, e.g., of

$$π \frac{{d}^{2}}{4} ,$$

where d is a nominal wafer diameter, of the underside of a wafer that a semiconductor processing tool is configured to process.

As shown in FIG. 2, the optical sensors 222 may be arranged in a triangular array, e.g., with the centers of the optical sensors 222 located at vertices in an equilateral triangle grid or lattice. This may be suitable for optical sensors in which the optical sensor captures an image of an entire circular field of view and may generally allow for the smallest number of optical sensors to completely cover a given circular area or region. For optical sensors in which the optical sensor captures an image of a rectangular sub-portion of a circular field-of-view, the optical sensors may be laid out in a rectangular, parallelogram, or other pattern while still allowing for the smallest number of optical sensors to be used to cover a given circular area.

In some implementations, as shown in FIG. 3, additional optical sensors 222′ may be placed in positions that do not align with any particular repeating pattern in order to provide additional imaging coverage and expand the composite field of view provided by the optical sensors 222. As can be seen, such an arrangement, including the placement of optical sensors 222′ near the outer perimeter of the substrate 202, may allow the composite field of view provided by the fields of view 223 to extend further past the footprint of the substrate 202. This may allow the optical sensors 222 and 222′ to be used to obtain a composite image of both the underside of the showerhead 252 immediately above the substrate 202 as well as a peripheral region of the underside of the showerhead 252 that extends beyond the perimeter of the substrate 202.

Imaging sensors used in a sensor-equipped wafer may, for example, be similar to those used in smartphones and other miniature electronic devices. For example, camera modules, including integrated optical lens systems (single- or multi-lens optical systems, for example, that may have a field of view of 30° or more, e.g., 40° or more, 50° or more, 60° or more, 70° or more, 80° or more, or even up to 180° or more, and a depth-of-focus on the order of 2 mm to 100 mm) designed for integration into smartphones and other portable electronic devices are widely available and may have a thickness on the order of 5 mm or less, allowing them to be integrated into a sensor-equipped wafer while still allowing the sensor-equipped wafer to have an overall maximum thickness that is on the order of 25 mm thick. Such a thickness allows the sensor-equipped wafer to be handled within a semiconductor processing tool in the same manner as a normal to-be-processed wafer without risking collision with components of the semiconductor processing chamber or other wafers that may be present within the semiconductor processing chamber. In some implementations, imaging sensors used in a sensor-equipped wafer may be coupled with optical lens systems providing a field of view of between 30° and 180°.

It will be appreciated that if imaging sensors are used as the optical sensors, such imaging sensors may be used to obtain either still image data or sequential image data, i.e., video data, that may depict the appearance of one or more components over time. For example, if a sensor-equipped wafer with one or more imaging sensors is oriented within a semiconductor processing chamber such that a slit valve or gate valve of the chamber is within the field of view of one or more such imaging sensors, the sensor-equipped wafer may be caused to obtain video footage from within the chamber of the slit valve or gate valve opening and/or closing, which may provide insight as to any potential mechanical issues with the operation of such components. In another example, such imaging sensors may be used to obtain video footage of, for example, the placement of an edge ring within the semiconductor processing chamber.

In some implementations, other arrangements of optical sensors may be used. FIG. 4 depicts an example optical sensor arrangement in which optical sensors 422 are arranged across only a portion of a substrate 402, e.g., spaced along a radius of the substrate 402. Alternatively, such optical sensors 422 may be located at different radial distances from the center of the substrate 402 but not necessarily along the same radius. In some such implementations, the optical sensors 422 may be arranged such that the centers of each optical sensor 422 are located at radial distances from the center of the substrate 402 that increase in 8 mm to 12 mm steps, e.g., 10 mm steps. For example, for a sensor-equipped wafer in which the substrate 402 is 300 mm in diameter, there may be on the order of 12 to 17, e.g., 13 to 16 or 14 to 15 optical sensors 422 arranged so as to each be positioned at a different radial distance from the center of the substrate 402 and such that the radial distances are generally evenly distributed (e.g., each radial distance being between X mm and Y mm greater than the next highest radial distance, with X and Y being on the order of 8 mm to 13 mm. Such an arrangement reduces the amount of wafer area that may need to be used to accommodate the optical sensors 422, thereby leaving additional room for accommodating other components, e.g., such as the various systems discussed with respect to FIG. 1. The lower number of optical sensors 422 may also result in reduced costs and lower power consumption. In some embodiments, other types of sensors (e.g., ambient atmospheric sensors or sound sensors) may occupy areas not occupied by the optical sensors.

Such an arrangement may be suitable for use in semiconductor processing tools in which it is unnecessary to obtain an image of most of the underside of a showerhead 452. For example, if it is known that a showerhead in a given semiconductor tool always has a circumferentially uniform or near-circumferentially uniform layer of undesired deposition film that gradually builds up on the underside thereof over time, an image or images along any given radius of the sensor-equipped wafer 400 may be sufficient to get a sense of what the film deposition is like across the entire underside of the showerhead. Similarly, if there is a portion or location of the underside of the showerhead that is known to see an accelerated level of deposition as compared with other portions of the underside of the showerhead, the sensor-equipped wafer 400 may be provided with one or more optical sensors, e.g., imaging sensors, that may be located so as to be placed directly under such a location or locations or so as to image an area containing such a location or locations.

It will be appreciated that arrangements of optical sensors such as are shown in FIG. 4 may also be used, in some contexts, to obtain images of a larger portion of the underside of a showerhead than may be imaged at one time with the sensor-equipped wafer of FIG. 4. For example, as shown in FIG. 5, a sensor-equipped wafer as shown in FIG. 4 may be caused to be rotated relative to the showerhead 452 in between when data regarding the underside of the showerhead are obtained using the optical sensors 422.

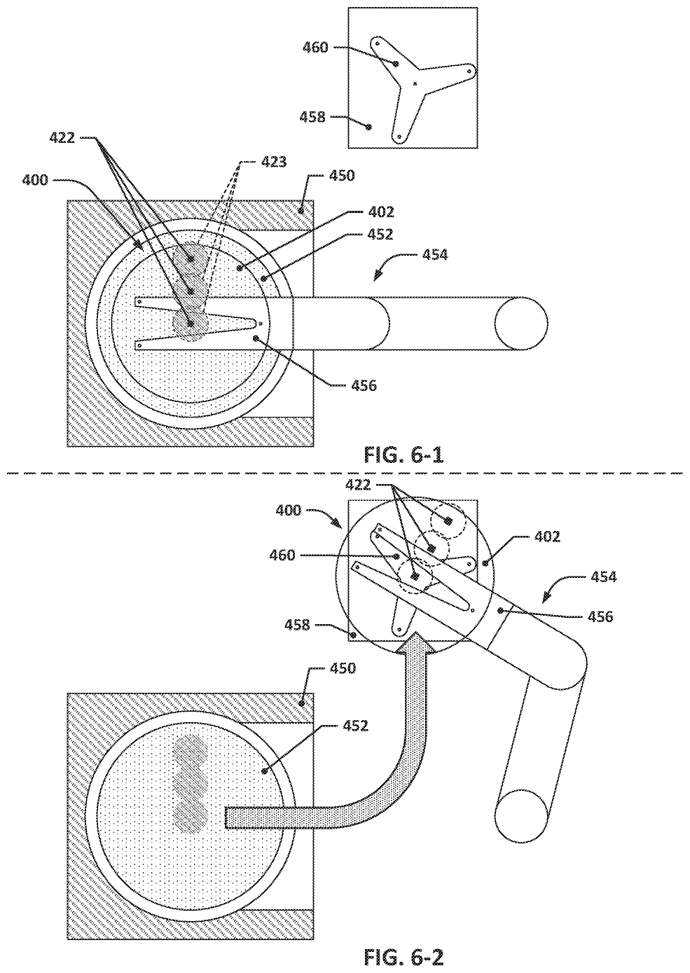

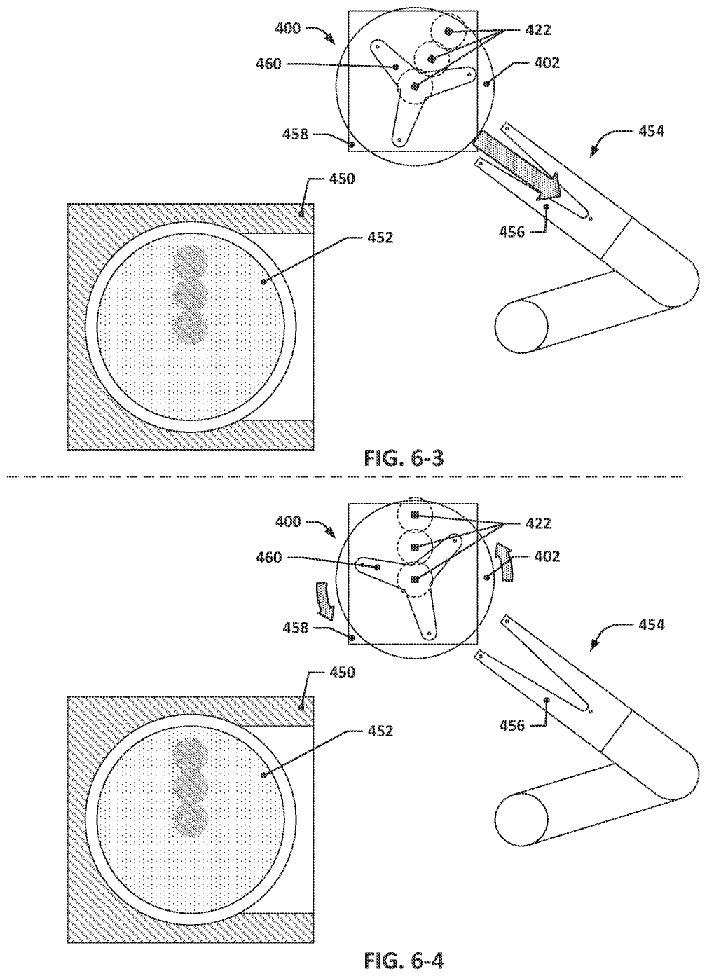

FIGS. 6-1 through 6-6, or example, depict various stages in one example of such a technique. In FIG. 6-1, a wafer handling robot 454 has been caused to reach into a semiconductor processing chamber 450 to retrieve the sensor-equipped wafer 400. Prior to such retrieval, the sensor-equipped wafer 400 has been caused to obtain data via the optical sensors 422 that have fields of view 423 that extend across a portion of the underside of the showerhead 452. The darker-shaded portion of the showerhead 452 represents the area of the showerhead 452 on which the data has been obtained. The sensor-equipped wafer 400 may, for example, be supported on a pedestal (not shown) within the semiconductor processing chamber 450 while the data is being obtained, and may then be raised off of the pedestal using a plurality of lift pins. With the sensor-equipped wafer 400 in a raised position, the wafer handling robot 454 may be caused to position a portion of the end effector 456 thereof underneath the sensor-equipped wafer 400. The lift pins may then be caused to retract into the pedestal, lowering the sensor-equipped wafer 400 onto the end effector 456.

In FIG. 6-2, the wafer handling robot 454 has been controlled so as to remove the sensor-equipped wafer 400 from the semiconductor processing chamber 450 and cause the sensor-equipped wafer 400 to be placed on a rotatable wafer support 460 of an aligner 458 or other mechanism that is configured to allow for rotational re-orientation of wafers placed thereupon. As can be seen, the darker shaded region in the shape of three overlapping circles within the semiconductor processing chamber 450 continues to represent the region of the showerhead 452 on which data has been obtained using the optical sensors 422.

In FIG. 6-3, the wafer handling robot has been caused to withdraw the end effector 456 from underneath the sensor-equipped wafer 400, leaving the sensor-equipped wafer 400 supported only by the rotatable wafer support 460. For example, the rotatable wafer support 460 may have three pins extending vertically upward therefrom. The three pins may act to support the sensor-equipped wafer 400 when the sensor-equipped wafer 400 is placed upon them, but may also be high enough that the gap between the rotatable wafer support 460 and the underside of the sensor-equipped wafer 400 when the sensor-equipped wafer 400 is supported by the pins is sufficient to allow clearance for the wafer handling robot to move the end effector 456 up and down so as to contact or disengage with the sensor-equipped wafer 400 and to allow the end effector 456 to be withdrawn from, or inserted into, the gap between the rotatable wafer support 460 and the sensor-equipped wafer 400.

In FIG. 6-4, the aligner 458 has been caused to rotate the rotatable wafer support 460 by a first angular amount, e.g., 30°, relative to the aligner 458. As can be seen, this causes the optical sensors 422 to be repositioned such that when the wafer handling robot 454 is caused to move the end effector 456 back under the sensor-equipped wafer 400, as shown in FIG. 6-5, the optical sensors 422 are located at a different angular orientation relative to the end effector 456 as compared to the rotational orientation the optical sensors 422 were in relative to the end effector 456 in FIG. 6-2.

In FIG. 6-6, the wafer handling robot 454 has been caused to place the rotated sensor-equipped wafer 400 back into the semiconductor processing chamber 450. As can be seen, the optical sensors 422 have fields of view 423 that now cover a different region of the underside of the showerhead 452 (although the optical sensor 422 at the center of the sensor-equipped wafer 400 will image the same region again). The process illustrated in FIGS. 6-1 through 6-6 may, it will be understood, be repeated as desired in order to obtain data from the optical sensors 422 for different regions, or all or substantially all, of the underside of the showerhead 452. For example, if the optical sensors 422 are imaging sensors, the technique discussed above may be used to obtain multiple sets of images with the sensor-equipped wafer 400 at different angular orientations so as to allow for a single composite image of the underside of the showerhead 452 to be obtained. In some implementations, the sensor-equipped wafer 400 may be rotated by a larger amount of rotation in between obtaining data from the one or more optical sensors, e.g., by an amount that is large enough that there are gaps between the regions of the showerhead 452 for which data is obtained for closest adjacent rotational positions.

In other implementations, multiple sets of optical sensors 422 that are present on the sensor-equipped wafer, such that data regarding a larger portion of the underside of the showerhead 452 may be obtained at any given rotational position, thereby allowing the sensor-equipped wafer 400 to be rotated fewer times and by a lesser total amount in order to obtain a desired level of data coverage for the underside of the showerhead 452. For example, if the sensor-equipped wafer 400 of FIGS. 6-1 through 6-6 instead had a line of optical sensors 422 that extended across the entire diameter of the sensor-equipped wafer 400 (instead of just along a radius thereof), a data for a given portion of the annular region around the centermost field-of-view could be obtained using the optical sensors 422 with half as many rotations being required as would be required with the arrangement shown in FIGS. 6-1 through 6-6.

It will be similarly recognized that the optical sensors 422 also need not be arranged in a line, as shown in FIGS. 6-1 through 6-6, in order to use the above-discussed technique. In some implementations, it may be sufficient to have at least one optical sensor 422 having a field of view that is off-center from the center of the sensor-equipped wafer 400, such that when the sensor-equipped wafer 400 is angularly re-oriented, the off-center optical sensor 422 rotates to a new rotational orientation, but also to a new XY position relative to a coordinate system that is fixed with respect to the showerhead 452. In some such implementations, there may be multiple optical sensors 422 that are each positioned at different radial distances from a center of the sensor-equipped wafer 400 such that if the sensor-equipped wafer 400 were to be continuously rotated in place underneath the showerhead 452, each such optical sensor 422 could be used to obtain data regarding visible characteristics of a different annular region on the underside of the showerhead 452.

It will be appreciated that in some implementations, the sensor-equipped wafer 400 may never actually be placed onto the pedestal in the semiconductor processing chamber. For example, the wafer handling robot 454 may simply support the sensor-equipped wafer 400 at all times within the semiconductor processing chamber 450. Thus, the wafer handling robot 454 may be caused to position the sensor-equipped wafer 400 within the semiconductor processing chamber 450 at a position centered under the showerhead 452 and the sensor-equipped wafer 400 then caused to obtain data regarding the visible characteristics of the underside of the showerhead 452. The wafer handling robot 454 may then withdraw the sensor-equipped wafer 400 from the semiconductor processing chamber 450 and place it on a mechanism may be used to cause the sensor-equipped wafer to rotate, after which the wafer handling robot 454 may again retrieve the sensor-equipped wafer 400 and insert it into the semiconductor processing chamber 450. The sensor-equipped wafer 400 may then be caused to obtain further data regarding visible characteristics of a different portion of the underside of the showerhead 452, again, while the sensor-equipped wafer 400 is supported by the wafer handling robot 454.

It will be further appreciated that the rotation of the sensor-equipped wafer 400 in between each acquisition of data using the optical sensor(s) 422 may, in some implementations, be performed using different equipment from the aligner 458. For example, in some implementations, a pedestal that may be used to support the sensor-equipped wafer 400 within the semiconductor processing chamber 450 may be equipped with a rotation capability. In such an implementation, the pedestal may simply be rotated while supporting, either directly or indirectly, the sensor-equipped wafer 400. Such an implementation allows for the sensor-equipped wafer 400 to be rotated relative to the showerhead 452 without requiring that the sensor-equipped wafer 400 be removed from the semiconductor processing chamber 450 in between rotation operations.

In another example, some wafer handling systems may have built-in wafer rotation capability. For example, in some multi-station semiconductor processing chambers, multiple, e.g., four, pedestals may be arranged in a circular array. Such semiconductor processing chambers may have a rotational indexer, e.g., a device with a rotatable central hub having four, equal-length, rigid arms extending outward therefrom at equally spaced positions around the central hub. Wafer supports located at the distal ends of the arms may be located such that each wafer supported thereby may be caused to move from a location centered over the center of a respective one of the pedestals to a location centered over the center of a respective other pedestal in the semiconductor processing chamber 450.

In some rotational indexers, the rotational indexer may be equipped with a mechanism that allows the wafer supports at the end of the rotational indexer arms to be rotated relative to the arms, e.g., while the rotational indexer is otherwise stationary. Thus, for example, a rotational indexer may be rotated so as to place one of the wafer supports thereof underneath a sensor-equipped wafer 400 (which may be lifted off the pedestal underneath it by, for example, lift pins to allow clearance for the wafer support to be so positioned). The sensor-equipped wafer 400 may then be placed on the wafer support and the wafer support caused to rotate. The sensor-equipped wafer 400 may then be removed from the wafer support, e.g., through being lifted upward by lift pins in the pedestal, and the indexer rotated so that the wafer support moves out from under the sensor-equipped wafer, thereby allowing the wafer, for example, to be lowered onto the pedestal in its new rotational orientation. Such indexers with the ability to rotate wafers without rotation of the indexer arms may, in some cases, be capable of rotating a wafer placed thereupon by any angle between 0° and 90°, allowing for a variety of sensor-equipped wafer rotation options.

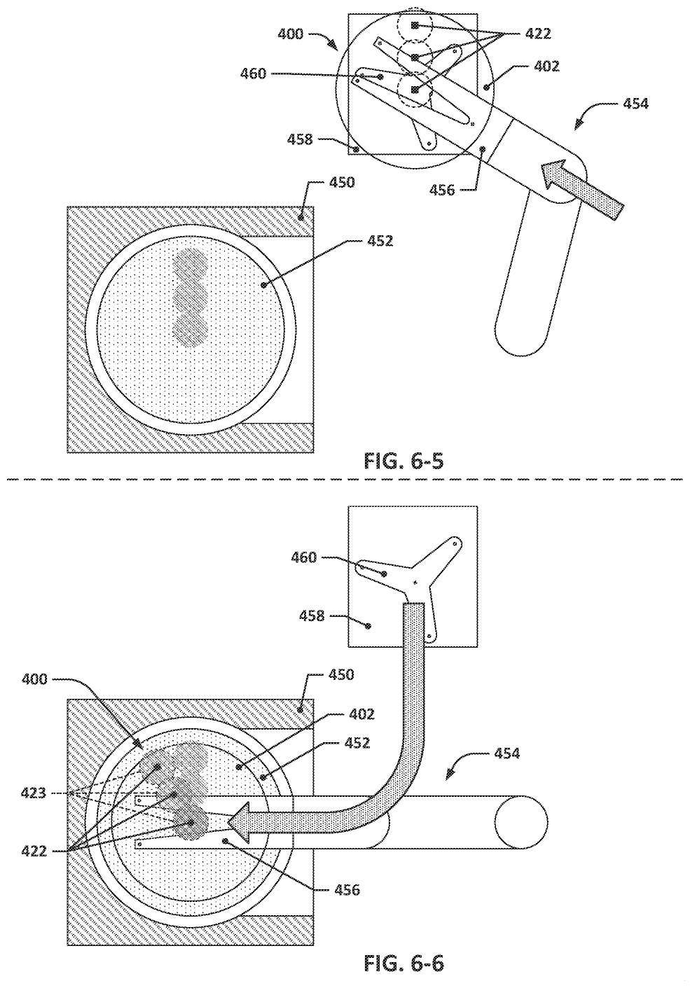

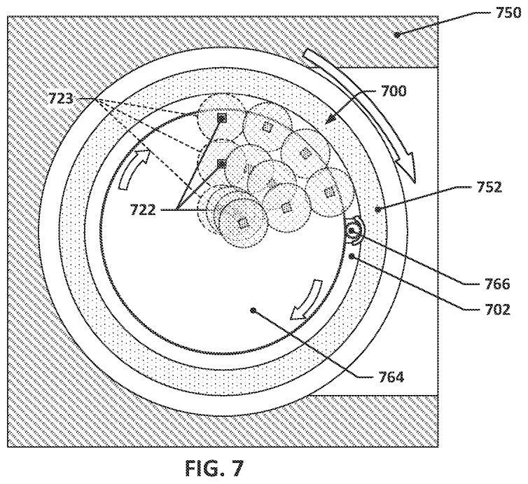

In a further implementation, as shown in FIG. 7, a sensor-equipped wafer may, itself, be equipped with the ability to rotate one or more optical sensors relative to the substrate thereof. In FIG. 7, a sensor-equipped wafer 700 having a substrate 702 is shown. The substrate 702 has a support structure 764 that is rotatably mounted with respect to the substrate 702. The substrate 702 may also support a rotational drive 766, e.g., a motor or other system, that is configured to cause the support structure 764 to rotate relative to the substrate 702 by at least a first rotational amount. In some implementations, the first rotational amount may be an amount less than 360°, although in other implementations, the first rotational amount may be 360° (or more than 360°).

One or more optical sensors 722 may be supported by the support structure 764 and oriented so that they have a field of view 723 that points upward, e.g., along a direction generally parallel to the axis of rotation about which the support structure 764 is configured to rotate. At least one of the one or more optical sensors 722 may be supported by the support structure 764 at a location that is radially offset from, e.g., in a direction perpendicular to, the rotational axis by at least some distance, e.g., such that rotation of the support structure 764 results in the field of view 723 of at least one of the first optical sensors supported by the support structure 764 to orbit around the rotational axis of the support structure 764. In some such implementations, there may be multiple such first optical sensors 722, each positioned at a different distance from the rotational axis, thereby allowing imaging of different annular zones of the underside of a showerhead 752 as the support structure 764 is rotated. For example, in FIG. 7, there are three such first optical sensors 722 arranged at three different distances from the rotational axis of the support structure 764. As the support structure 764 is caused to be rotated by the rotational drive 766, the first optical sensors 722 orbit around the rotational axis at different distances, thereby each having a field of view 723 that sweeps across one of several different annular zones on the underside of the showerhead 752.

In some implementations, other electronics, e.g., a controller, power source, communications interface, etc., for the sensor-equipped wafer 700 may also be mounted to the support structure 764 so that all of the electronics rotate together with the support structure 764. In other implementations, however, at least some of the other electrical components of the sensor-equipped wafer 700 may be mounted on the substrate 702. In such implementations, the one or more optical sensors 722 may be electrically connected, either directly or indirectly, with one or more of the electrical components mounted to the substrate 702 via, for example, a flexible cable. Alternatively, such an electrical connection may be provided via conductive pathways integrated into, for example, a bearing assembly that is used to rotatably support the support structure—for example, the electrical connection may be provided by a slip ring connection.

In such sensor-equipped wafers, the controller thereof may be controlled so as to cause one or more control signals to be provided to the rotational drive 766. The control signals may cause the rotational drive 766 to rotate, thereby causing the support structure 764 (and the optical sensor(s) 722 mounted thereto) to rotate relative to the substrate 702. Through such rotation, the optical sensor(s) 722 may be caused to shift between different rotational positions relative to the substrate 702, thereby allowing data for different regions of the underside of the showerhead 752 to be collected using the optical sensor(s) 722. In some implementations, such data may be obtained from the optical sensor(s) 722 continuously while the support structure 764 is caused to rotate, with the optical sensor(s) 722 acting, in effect, as a rotational scanner. In other implementations, the optical sensor(s) 722 may be caused to obtain such data in between rotations of the support structure 764.

In some implementations, a sensor-equipped wafer configured for use in a particular semiconductor processing tool may incorporate a substrate that is sized smaller than the size of wafers that that semiconductor processing tool is configured to process. For example, if a semiconductor processing tool is configured to process 300 mm wafers, such a sensor-equipped wafer may be, for example, 200 mm or less, 150 mm or less, or 100 mm or less in diameter. Such sensor-equipped wafers may, for example, have a substrate with a diameter that is 60% or less, e.g., 50%, of the nominal wafer diameter of wafers that are typically processed in a semiconductor processing chamber that such sensor-equipped wafers are intended to be used within. For example, in some instances, an end effector that supports semiconductor wafers during wafer transport operations in a semiconductor processing tool (and which would be used to transport a sensor-equipped wafer as well) may contact a 300 mm wafer across a 50 mm diameter contact area, in which case the sensor-equipped wafer may have a diameter that is as low as 17% of the diameter of the nominal diameter of wafers that are typically processed in a semiconductor processing chamber and may still be supported by that end effector.

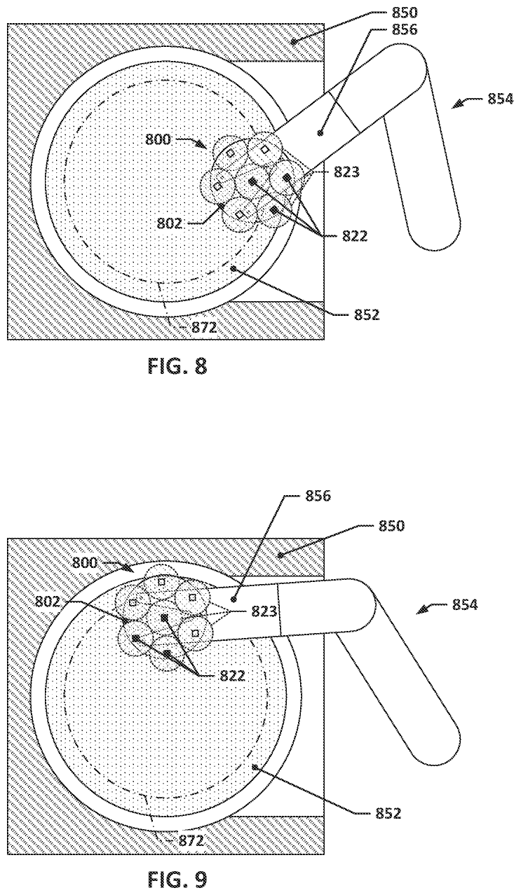

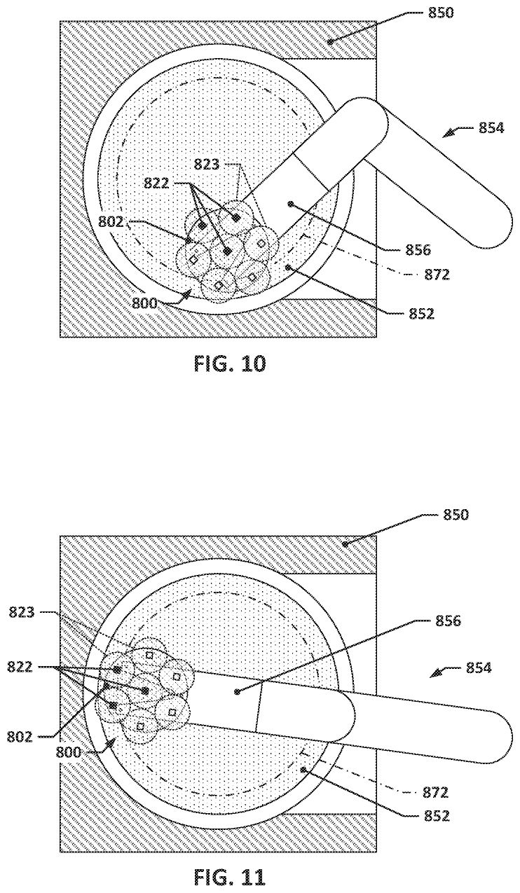

In such implementations, the smaller substrate size will limit the space available for supporting optical sensors—however, such a sensor-equipped wafer may offer more positional flexibility due to its smaller size. FIGS. 8 through 11 show diagrams of a smaller-diameter sensor-equipped wafer. In FIGS. 8 through 11, a semiconductor processing chamber 850 is shown that contains a showerhead 852. A wafer footprint 872 that represents the typical location/footprint of semiconductor wafers within the semiconductor processing chamber during wafer processing operations is shown beneath the showerhead 852. A wafer-handling robot 854 is shown that has an end effector 856 that is used to support a sensor-equipped wafer 800. The sensor-equipped wafer 800 has a substrate 802 that supports a number of optical sensors 822 that have upward-facing fields of view 823. In this example, there are seven optical sensors 822, although it will be appreciated that more or fewer may be used as well.

The substrate 802, it will be noted, has a smaller diameter than the diameter of the wafers that are typically processed within the semiconductor processing chamber 850, as indicated by the disparity in size between the wafer footprint 872 and the substrate 802. This allows the sensor-equipped wafer 800 to be moved between different positions within the semiconductor processing chamber, e.g., as shown in FIGS. 8 through 11, so that data regarding visible characteristics of different portions of the showerhead 852 may be obtained. Such an arrangement may allow such a sensor-equipped wafer to obtain optical data on a region of a showerhead that is much larger than the aggregate field of view of the optical sensors housed on such a sensor-equipped wafer.

It will be understood that in such implementations, the sensor-equipped wafer may have more or fewer optical sensors from the seven depicted. The sensor-equipped wafer may even have only a single optical sensor (or a single optical sensor of a particular type of optical sensor). In some implementations, a controller of a semiconductor processing tool, e.g., with one or more processors and one or more memory devices, may be controlled via computer-executable instructions stored therein to control a wafer-handling robot to retrieve such a sensor-equipped wafer, e.g., from a storage location or other location outside of a semiconductor processing chamber of the semiconductor processing tool, and then insert it inside a semiconductor processing chamber of the semiconductor processing tool. The instructions may further cause the wafer-handling robot to move the sensor-equipped wafer between different locations within the semiconductor processing chamber and to send one or more commands to the sensor-equipped wafer to cause the sensor-equipped wafer to obtain data regarding visible characteristics of the underside of the showerhead at each such location. Such optical data may then be retrieved from the sensor-equipped wafer and analyzed, e.g., used to generate a composite image of the underside of the showerhead.

As noted earlier, the optical sensors that are used may, for example, be imaging sensors, such as charge-coupled devices (CCDs) or other pixel-based imaging sensors. Such optical sensors may be used, in some cases, with no external sources of illumination. In other implementations, a sensor-equipped wafer having one or more optical sensors may also include one or more illumination devices or systems that may be configured to provide a desired form of illumination. In some such examples, an illumination source (e.g., a light source) may be used that provides diffuse, relatively uniform light across the surface to from which data is to be obtained using the optical sensor(s). For example, one or more light-emitting diodes, electroluminescent panels, or other light-emitting structures may be mounted to the side of the sensor-equipped wafer 400 that faces towards the showerhead 452 such that light, e.g., light in a particular light spectrum or broad-spectrum, e.g., white, light may be directed upward at the underside of the showerhead 452 by the sensor-equipped wafer 400. In some such implementations, a diffuser material, e.g., a diffusive optically transmissive medium, may be placed over the light-emitting structures so as to more evenly distribute the illumination and prevent or mitigate potential specular reflection that may obscure visible characteristics that are intended to be captured by the optical sensor(s).

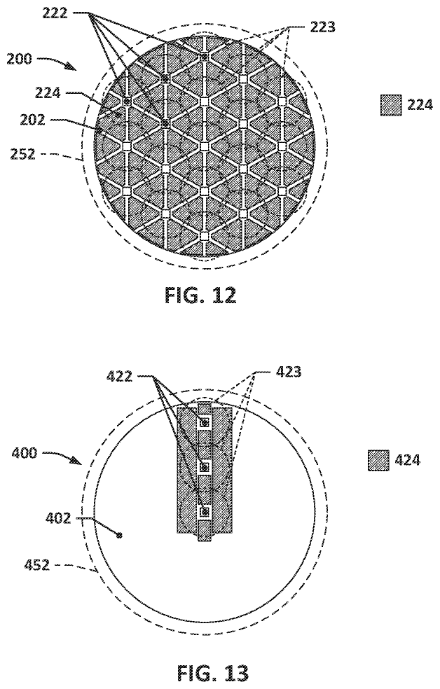

FIGS. 12 and 13 depict examples of sensor-equipped wafers similar to those discussed with respect to FIGS. 2-5 but with the addition of illumination sources that may be used to illuminate the surface that the optical sensors (imaging sensors) thereof are configured to obtain optical data from. For example, FIG. 12 depicts the sensor-equipped wafer 200 of FIG. 2, but with the addition of illumination devices 224 arrayed across the upper surface of the substrate 202. The illumination devices 224, in this example, are electroluminescent panels or LEDs that are generally triangular in shape and are arranged such that the corners of each triangular panel are generally adjacent to different ones of the optical sensors 222. Such illumination devices 224 may be caused to be illuminated in order to direct light towards the surface of whatever lies above the sensor-equipped wafer, e.g., the underside of the showerhead 252. As noted above, the illumination devices 224 may, in some cases, include a layer of diffusive material that acts to diffuse the light emitted from the illumination devices 224 and thereby mitigate or prevent specular reflection off of the surface being imaged.

FIG. 13 depicts the sensor-equipped wafer 400 of FIG. 4, but with the addition of illumination devices 424. The illumination devices 424, in this example, are rectangular electroluminescent panels or LEDs that are positioned on either side of, in between, and on either end of the three optical sensors 422 that are shown. Such illumination devices may, in some instances, include a layer of diffusive material, as with the example of FIG. 12.

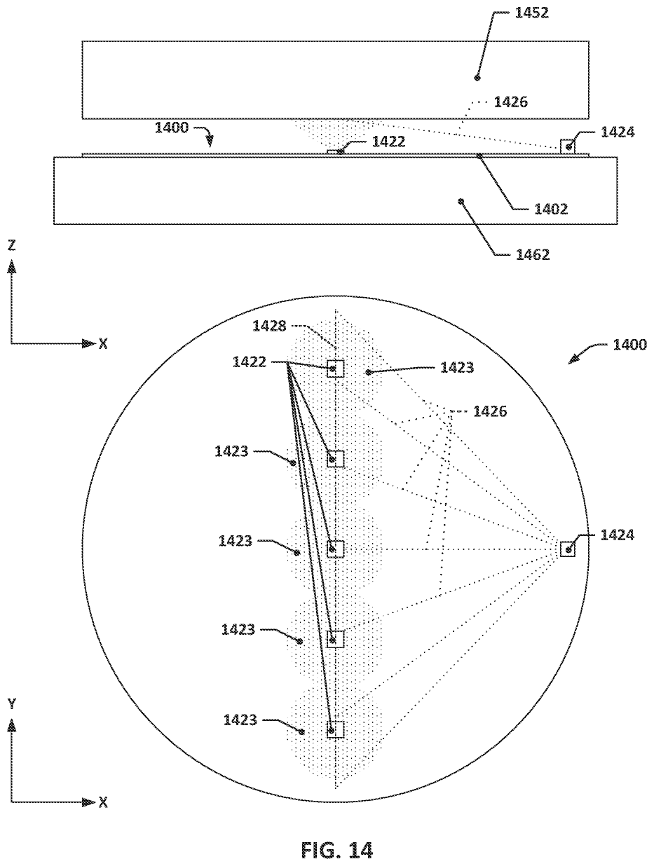

In some implementations of sensor-equipped wafers with illumination sources, an illumination source may be provided that projects a structured image along an axis that is at an oblique angle relative to the sensor-equipped wafer 4002 substrate 402, e.g., an oblique angle with respect to a second side of the substrate 402 (with the first side of the substrate 402 facing towards and/or contacting the pedestal and the second side of the substrate 402 facing upward towards the showerhead). For example, an illumination source that projects a straight line that is parallel to, and coincident with, a plane that is at an oblique angle to the substrate 402 may be used. Such an illumination source may, for example, be provided using a laser diode coupled with a diffractive optical element that disperses the collimated light produced by the laser diode into a line. When such an illumination pattern is projected onto a reference plane that is parallel to the substrate 402 (and that is further from the first side of the substrate than the second side of the substrate), the projected light will intersect with that reference plane along a line. Thus, if the reference plane is, for example, the underside of the showerhead 452 and the underside of the showerhead 452 is flat and parallel to the substrate 402, the light that strikes the underside of the showerhead 452 will form a straight line. FIG. 14 depicts a schematic of this.

FIG. 14 has a top portion that shows a side view of a sensor-equipped wafer 1400 supported by a pedestal 1462 underneath a showerhead 1452 and a bottom portion that shows a plan view of the same structures. The sensor-equipped wafer 1400 includes a substrate 1402 that has mounted thereupon a plurality of optical sensors 1422 that are arranged along a diameter of the sensor-equipped wafer 1400. Also supported by the substrate 1402 is an illumination device 1424, which, in this example, is a laser diode coupled with a diffractive optic that spreads the collimated beam of light emitted by the laser diode into a two-dimensional, fanned-out optical beam 1426. The fanned-out optical beam is parallel to and coincident with a plane that is perpendicular to the page, i.e., that is parallel to the Y axis of the indicated coordinate system, and parallel to the dotted line indicating the optical beam 1426.

When the underside of the showerhead 452 is flat and perfectly parallel to the substrate 1402, as shown in FIG. 14, the fanned-out optical beam will generate an illumination pattern 1428 that is a straight line. Optical sensors 1422, which may be imaging sensors, may be positioned on the substrate 1402 such that the illumination pattern 1428 is within the collective fields of view 1423 of the optical sensors 1422. Thus, if an image of the underside of the showerhead 1452 is obtained with the optical sensors 1422 while the illumination pattern 1428 is projected onto the underside of the showerhead 1452, the resulting composite image will show the illumination pattern 1428 as a straight line.

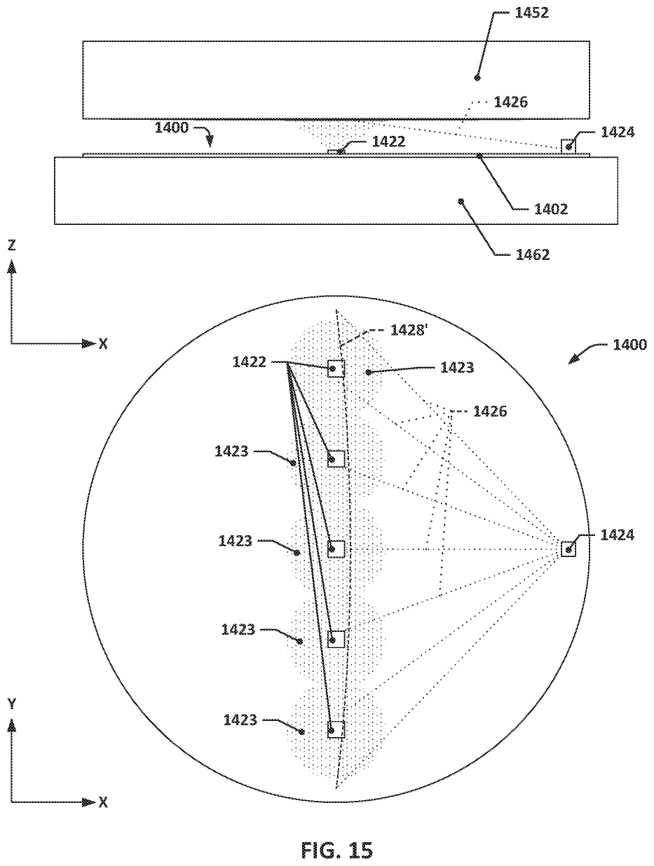

However, if the underside of the showerhead 1452 where the optical beam falls is uneven due to deposition occurring on the underside of the showerhead 1452, the fanned-out optical beam will strike the underside of the showerhead at different locations than as shown in FIG. 14. For example, FIG. 15 is the same as FIG. 14 except that the underside of the showerhead 1452 has a slight bulge to it, e.g., as may be caused by deposition on the showerhead 1452 underside that is thickest near the center of the showerhead and then decreases in thickness near the edge of the showerhead 1452.

As a result of the bulge, the optical beam 1426 that strikes the underside of the showerhead 1452 does so at different locations from where it would in the ideal case, e.g., as shown in FIG. 14. This is due to the fact that the optical beam strikes the underside of the showerhead at a shallow angle; any change in the altitude at which the optical beam strikes the underside of the showerhead will also generally result in a lateral (XY shift) in location for the intersection point. In the case of the shallow dome-shaped profile of the underside of the showerhead 1452 shown in FIG. 15, the formerly straight-line illumination pattern, as shown in FIG. 14, instead appears as a slightly curved illumination pattern 1428′. The amount of maximum deviation from the straight-line illumination pattern 1428 to the curved illumination pattern 1428′ indicates the amount of maximum non-uniformity that exists in the thickness of the deposited material on the underside of the showerhead 1452.

In some implementations, a second illumination pattern may be provided using a second illumination device. The second illumination pattern may be projected onto the underside of the showerhead in a way that minimizes or eliminates the amount of distortion that the second illumination pattern may undergo when projected onto the underside of the showerhead 1452 when the underside is not flat and/or parallel to the substrate 1402.

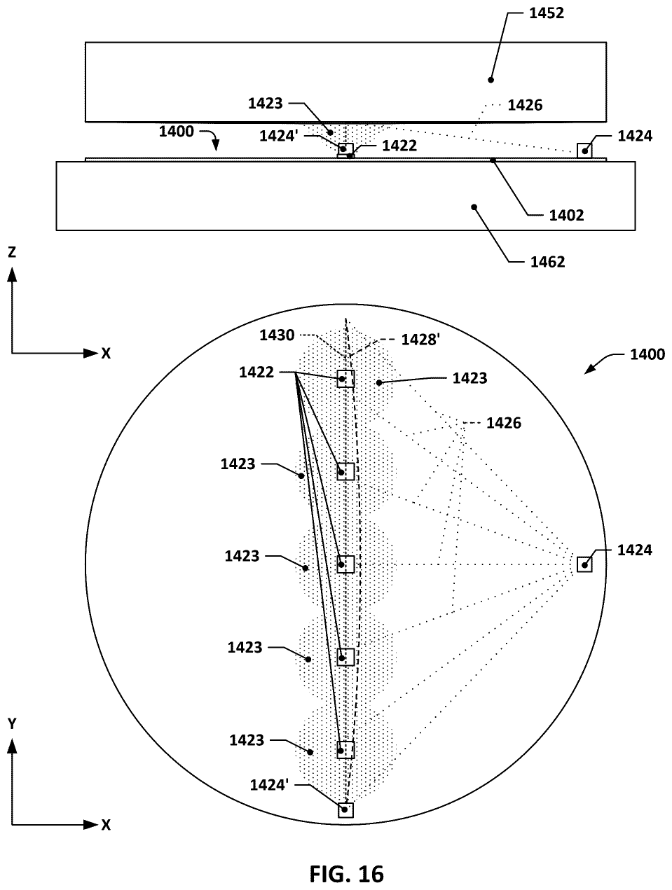

FIG. 16 depicts the same elements as are depicted in FIG. 15, except that the sensor-equipped wafer 1400 further includes a second illumination device 1424′ that is configured to project a reference illumination pattern 1430 onto the underside of the showerhead 1452 in a manner that makes it generally immune to distortion similar to that experienced by the illumination pattern 1428′. For example, the reference illumination pattern 1430 may similarly be a fanned-out optical beam from a laser diode, but may be projected such that the fanned-out beam is perpendicular to the substrate 1402 and parallel to a line formed by the intersection of the illumination pattern 1428 and a plane, e.g., a reference plane, that is parallel to the substrate 1402. Thus, the fanned-out optical beam that forms the reference illumination pattern 1430 may, in effect, act as a vertical plane that intersects with the underside of the showerhead 1452 but which does not experience any shift in intersection location in directions perpendicular to the vertical plane. As a result, the reference illumination pattern 1430 will remain linear, and may provide a basis for comparison with the illumination pattern 1428′. As can be seen, the optical sensors 1422 may be positioned so as to be able to simultaneously image both the reference illumination pattern 1430 and the illumination pattern 1428′. In the event that the illumination pattern 1428′ is linear, e.g., as shown by FIG. 14's illumination pattern 1428, then the illumination pattern 1428′ and the reference illumination pattern 1430 may be parallel or even, depending on the positioning of the two patterns, colinear.

It will be understood that the illumination pattern 1428 may take any of a variety of different forms, including, for example, a rectangular grid pattern, a rectangular array of “+” symbols, a rectangular array of dots, a pattern of concentric circles, a rectangular pattern of circles, etc. The illumination patterns may also be non-repeating arrangements of shapes. The single-line patterns used in FIGS. 14 through 16 provide an easily understood example, but it will be apparent that generally any illumination pattern that is projected onto the underside of the showerhead 1452 at an oblique angle will be distorted when projected onto a non-planar showerhead underside as compared with a planar showerhead underside, and that the amount of such distortion, as imaged by optical sensors 1422 located generally directly below locations where the illumination pattern strikes the underside of the showerhead 1452, will provide insight as to the deviation of the underside of the showerhead from a perfectly flat surface that is parallel to the substrate 1402.

It will be further recognized that the determination of what the level of deviation due to a non-flat showerhead 1452 underside is in a given illumination pattern may be achieved through a variety of mechanisms. For example, the illumination pattern as recorded by the optical sensor(s) of the sensor-equipped wafer 1400 may be compared against a known or expected illumination pattern, e.g., if it is known that the illumination pattern 1428 should produce a straight line, then the illumination pattern as recorded by the optical sensors may be evaluated to determine how far it deviates from a straight line.

In other implementations, as discussed above, a reference illumination pattern that is immune to distortion (in at least one direction) due to variations in the contour of the underside of the showerhead 1452 may also be projected onto the underside of the showerhead 1452 so that the optical sensors 1422 can be used to obtain image data of both the illumination pattern 1428 and the reference illumination pattern 1430, thereby allowing for a direct comparison between the two imaged patterns. It will be appreciated that the reference illumination pattern 1430 and the illumination pattern 1428 may be projected onto the underside of the showerhead 1452 at different, non-overlapping times and separate images taken of each pattern. If the sensor-equipped wafer is not moved in between taking such pictures, then it may be relatively straightforward to evaluate the amount of deviation between the two patterns using the two images.

In yet further implementations, the sensor-equipped wafer may be used to obtain an initial calibration image of the underside of the showerhead 1452 while the illumination pattern is projected thereupon. Such a calibration image may be obtained while the showerhead 1452 is still in a pristine state, e.g., prior to when the showerhead 1452 is first exposed to gases that may deposit a film on the underside thereof, thereby potentially altering the contour of the underside of the showerhead 1452. This calibration image may then be retained and compared with future images of projections of such an illumination pattern on the underside of the showerhead with the sensor-equipped wafer positioned in the same location and orientation within the semiconductor processing chamber. Deviations between the illumination pattern as shown in the calibration image and the illumination pattern as shown in later images, e.g., obtained after the showerhead underside may have experienced changes in underside contour due to incidental deposition, may then be identified and quantified to provide an indication of the degree of showerhead underside non-uniformity.

In some implementations, one or more optical sensors may be provided on a sensor-equipped wafer and oriented such that the optical sensor or sensors have a field of view that is directed radially outward, e.g., towards a side wall of a semiconductor processing chamber or towards components located in the side wall of the semiconductor processing chamber. FIG. 17 depicts an example of a sensor-equipped wafer with optical sensors that are configured to have radially outward-facing fields of view. In FIG. 17, a substrate 1702 for a sensor-equipped wafer 1700 is shown. A plurality of optical sensors 1722 are positioned at spaced-apart locations along an outer perimeter of the substrate 1702 and oriented such that they have fields of view 1723 that are directed radially outward from the substrate 1702. In the depicted example, the optical sensors 1722, which may be imaging sensors, are spaced apart such that they have circumferentially overlapping fields of view 1723 at a given radial distance from the center of the sensor-equipped wafer 1700. For example, the fields of view 1723 may circumferentially overlap at a radial distance from the center of the sensor-equipped wafer 1700 that is equal to the distance between an interior wall surface of a semiconductor processing chamber 1750 that the sensor-equipped wafer 1700 is positioned within and the center of the sensor-equipped wafer 1700 (or the distance between the interior wall surface and a center axis of a pedestal that the sensor-equipped wafer 1700 is positioned upon when placed in the semiconductor processing chamber).

When arranged in such a manner, the data obtained from the optical sensors 1722, e.g., image data, may be processed to provide a single data set that represents optical data obtained from the entire circumference of a portion of an interior wall or walls of the semiconductor processing chamber (or other structures, e.g., slit valves through which wafers may be introduced to/removed from the semiconductor processing chamber). Thus, for example, a single composite panoramic image of the interior wall surfaces of the semiconductor processing chamber 1750 may be obtained using such a sensor-equipped wafer.

It will also be recognized that the spacing between the optical sensors 1722 may be great enough that some or all of the fields of view 1723 of the optical sensors 1722 do not overlap in such a manner, and that there may thus be regions of the interior wall surfaces of the semiconductor processing chamber 1750 for which data from the optical sensor(s) 1722 is not obtained. In some implementations, the optical sensor(s) 1722 may be placed at a location or locations that, then the sensor-equipped wafer 1700 is placed into the semiconductor processing chamber 1750 in a predefined orientation, align with, and are oriented towards, one or more locations for which data from the optical sensors 1722 is desired. Such locations, for example, may include locations where it is known or expected that elevated levels of undesired deposition (or other semiconductor processing byproduct or effect) may occur, or areas where components that may have particular sensitivities to such deposition or other processing operations may exist. For example, one or more such optical sensors 1722 may be positioned so as to be located at a location along the outer perimeter of the sensor-equipped wafer located proximate to, and with fields of view 1723 oriented towards, a slit valve that is used to seal a wafer transfer passage through which the sensor-equipped wafer may be passed when introduced into the semiconductor processing chamber 1750. Such slit valves may be more susceptible to potential damage, e.g., by undesired deposition or etching or through normal wear and tear. For example, such a slit valve may have an elastomeric seal that acts to seal the slit valve door to the semiconductor processing chamber 1750 so as to provide a gas-tight interface. Such a seal may, each time the slit valve is opened or closed, undergo wear. If a sensor-equipped wafer with optical sensors 1722, e.g., image sensors, is provided as suggested, such optical sensors 1722 may be used to obtain data, e.g., an image or images, regarding the slit valve. Such data may allow the condition of the seal to be evaluated without requiring that the semiconductor processing chamber be opened or the slit valve disassembled.

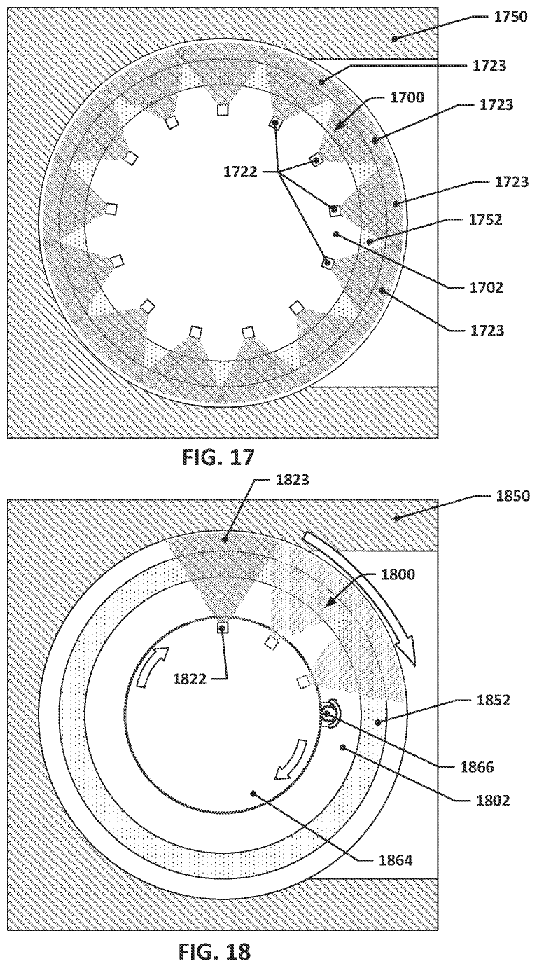

In some implementations, a sensor-equipped wafer may be provided with one or more radially outward-facing optical sensors that are mounted to a support structure that is rotatably mounted with respect to a substrate; an example of such a sensor-equipped wafer is shown in FIG. 18.

In FIG. 18, a sensor-equipped wafer 1800 having a substrate 1802 is shown. The substrate 1802 has a support structure 1864 that is rotatably mounted with respect to the substrate 1802. The substrate 1802 may also support a rotational drive 1866, e.g., a motor or other system, that is configured to cause the support structure 1864 to rotate relative to the substrate 1802 by at least a first rotational amount. As shown, the rotational drive 1866 has a gear engages with gear teeth along the exterior of the support structure 1864, although alternate implementations may use a linkage-based mechanism (e.g., a crank arm coupled with a linear actuator), a friction drive mechanism (e.g., a wheel with an elastomeric outer rim that is compressed against the exterior of the support structure 1864), etc. In some implementations, the first rotational amount may be an amount less than 360°, although in other implementations, the first rotational amount may be 360° (or more than 360°).

One or more optical sensors 1822 may be supported by the support structure 1864 and oriented so that they have a field of view 1823 that points, for example, radially outward from the center of rotation of the support structure 1864. In some implementations, other electronics, e.g., a controller, power source, communications interface, etc., for the sensor-equipped wafer 1800 may also be mounted to the support structure 1864 so that all of the electronics rotate together with the support structure 1864. In other implementations, however, at least some of the other electrical components of the sensor-equipped wafer 1800 may be mounted on the substrate 1802. In such implementations, the one or more optical sensors 1822 may be electrically connected, either directly or indirectly, with one or more of the electrical components mounted to the substrate 1802 via, for example, a flexible cable. Alternatively, such an electrical connection may be provided via conductive pathways integrated into, for example, a bearing assembly that is used to rotatably support the support structure—for example, the electrical connection may be provided by a slip ring connection.

In such sensor-equipped wafers, the controller thereof may be controlled so as to cause one or more control signals to be provided to the rotational drive 1866. The control signals may cause the rotational drive 1866 to rotate, thereby causing the support structure 1864 (and the optical sensor 1822 mounted thereto) to rotate relative to the substrate 1802. Through such rotation, the optical sensor(s) 1822 may be caused to shift between different rotational positions relative to the substrate 1802, thereby allowing data for regions of the interior wall(s) of a semiconductor processing chamber 1850 at different rotational positions to be collected using the optical sensor(s) 1822. In some implementations, such data may be obtained from the optical sensor(s) 1822 continuously while the support structure 1864 is caused to rotate, with the optical sensor(s) 1822 acting, in effect, as a rotational scanner. In other implementations, the optical sensor(s) 1822 may be caused to obtain such data in between rotations of the support structure 1864.

It will also be understood that a sensor-equipped wafer having a support structure that is configured to be rotatable relative to the substrate of the sensor-equipped wafer, e.g., as described above, may also be used with optical sensors that have upward-facing fields of view, e.g., as in sensor-equipped wafers discussed earlier with respect to FIG. 4. For example, the support structure may support one or more optical sensors that face upwards, e.g., have fields of view with lines of sight that are perpendicular, or near-perpendicular to the substrate. At least one of such optical sensors may be positioned at a distance that is radially offset from the rotational axis of the support structure, such that the offset optical sensor(s) follow a circular path when the support structure is caused to rotate relative to the substrate. In such systems, the support structure may be caused to rotate in order to position the optical sensor(s) supported thereby under different locations on the underside of the showerhead, allowing for optical data to be collected from different regions of the showerhead underside.

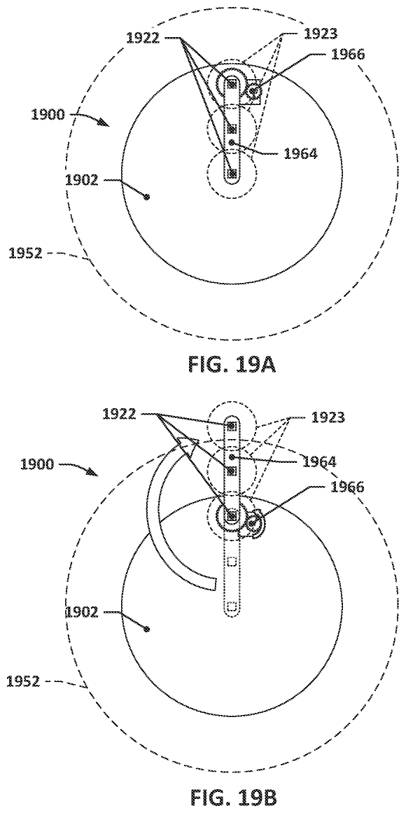

In another type of sensor-equipped wafer, optical sensors may be located on support structures that may be moved so as to reposition the optical sensors to locations that are a further distance from the center of the sensor-equipped wafer. FIGS. 19A and 19B depict such a sensor-equipped wafer in two different states of operation. As can be seen in FIG. 19A, a sensor-equipped wafer 1900 is provided that includes a substrate 1902 and a support structure 1964 that is rotatably connected with the substrate 1902. The support structure 1964 is configured to be rotatable relative to the substrate 1902 about an axis that is located off-center from the center of the substrate 1902, e.g., about an axis that is located near the edge of the substrate 1902. A rotational drive 1966 is coupled with the support structure 1964 such that when the rotational drive 1966 is caused to rotate, the support structure 1964 rotates as well—this is shown in FIG. 19B, in which the rotational drive 1966 has been caused to rotate, thereby causing the support structure 1964 to rotate by 180° relative to the substrate 1902. Thus, the support structure 1964 has rotated from a position in which it points inwards towards the center of the substrate 1902 to a position in which it points outwards from the substrate 1902.

The support structure 1964 may, as shown, support one or more optical sensors 1922 with fields of view 1923. When the support structure 1964 is caused to swing outboard of the substrate 1902 through actuation of the rotational drive 1966, this causes the optical sensors 1922 to be positioned at locations radially outward from the locations such optical sensors 1922 were in, e.g., as shown in FIG. 19A. This may allow the sensor-equipped wafer 1900 to obtain optical data from a component that is significantly larger than the footprint of the substrate 1902. For example, in FIGS. 19A and 19B, the outline of a showerhead 1952 is shown that is much larger in diameter than the diameter of the sensor-equipped wafer 1900. The optical sensors 1922 may be repositioned, as shown in FIG. 19B, so as to capture optical data of the portion of the showerhead 1952 that lies beyond the outer perimeter of the substrate 1902. It will also be recognized that such an implementation may also allow for the optical sensors to capture optical data from locations above the interior of the substrate 1902 where there may otherwise not be any structure. For example, if the substrate 1902 is annular in shape, i.e., with an opening in the center, such an implementation would allow the optical sensors to be repositioned over the opening so as to be able to capture optical data of the region of the showerhead that is over the opening.

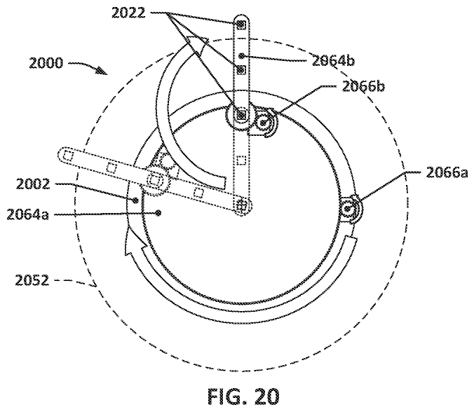

In some implementations, the implementation of FIGS. 19A and 19B may implemented on a sensor-equipped wafer sharing some similarities with the sensor-equipped wafer 700 of FIG. 7. FIG. 20 depicts an example of such a sensor-equipped wafer. In FIG. 20, a sensor-equipped wafer 2000 is shown that includes support structures 2064a and 2064b. The first support structure 2064a is rotatably supported by a substrate 2002 (for example, the first support structure 2064a may be coupled to the substrate 2002 via a rotational bearing), while the second support structure 2064b is rotatably supported by the support structure 2064a. Thus, the first support structure 2064a may be caused to rotate relative to the substrate 2002 and about a center axis thereof responsive to rotational input provided by a first rotational drive 2066a, while the second support structure 2064b may be caused to rotate relative to the first support structure 2064a about a rotational axis that is radially offset from the center axis of the substrate 2002 responsive to rotational input provided by a second rotational drive 2066b.

Such a configuration allows the second support structure 2064b to be rotated between different positions, thereby causing at least some optical sensors 2022 located on the second support structure 2064b to be moved between different radial positions relative to the center of the substrate 2002 (this is represented by the dotted outlines of the second support structure 2064b and the optical sensors 2022 in FIG. 20). Additionally, the first support structure 2064a may be rotated to cause the optical sensors 2022 located on the second support structure 2064b to rotate to different azimuthal positions relative to the substrate 2002 (also indicated by dotted outlines in FIG. 20). Such an implementation may, for example, be used to obtain optical data across the entire underside of a showerhead (represented by the dashed outline of a showerhead 2052 in FIG. 20) that is much larger than the footprint of the substrate 2002. For example, the first support structure 2064a may be caused to rotate relative to the substrate 2002 while the second support structure 2064b is oriented to point inwards towards the rotational center of the first support structure 2064a. During such rotation, the optical sensors 2022, which may be upward-looking imaging sensors, may be caused to periodically obtain optical data, e.g., images, of the underside of the showerhead that is above the substrate 2002 during such rotation. The second support structure 2064b may then be caused to rotate by 180° (or, more generally, by between 90° and 180°) relative to the first support structure 2064a so as to place at least some of the optical sensors 2022 outboard and some of the second support structure 2064b of the substrate 2002. The first support structure 2064a may then be caused to rotate relative to the substrate 2002 with the second support structure 2064b in the partially outboard position. Further optical data may then be periodically obtained from the optical sensors 2022 of the underside of the showerhead 2052 that is outboard of the substrate 2002 during such rotation. The optical data that is collected during such rotations of the first support structure 2064a may then be composited together to form a composite data set representing the entire underside of the showerhead 2052. Such sensor-equipped wafers may thus facilitate collecting optical data, e.g., image data, from showerheads that are larger (e.g., at least up to 25% or 50% larger) in diameter than the diameter of the substrates of such sensor-equipped wafers.

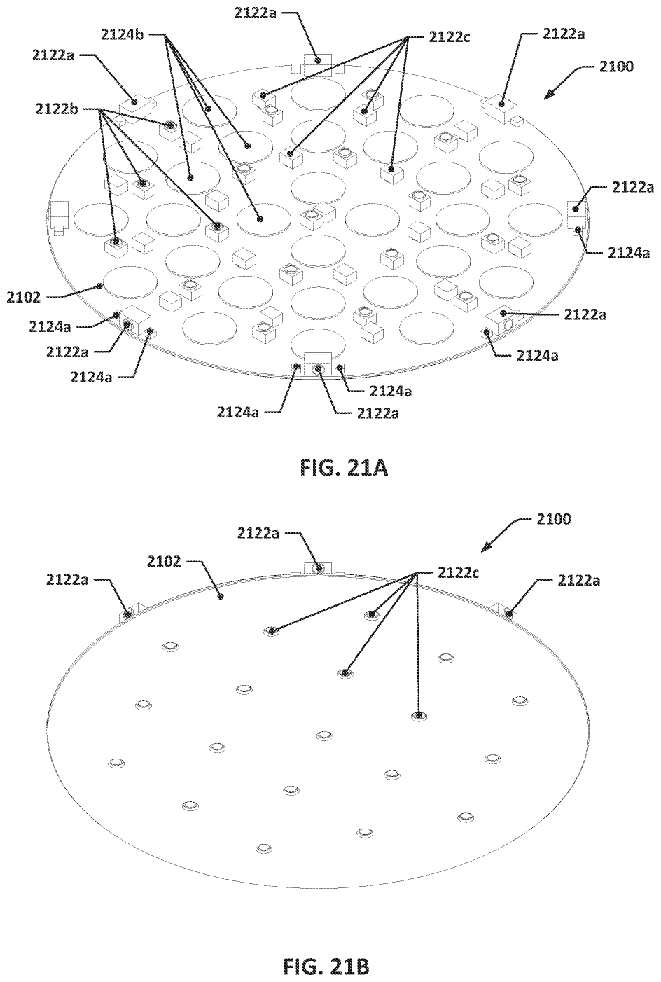

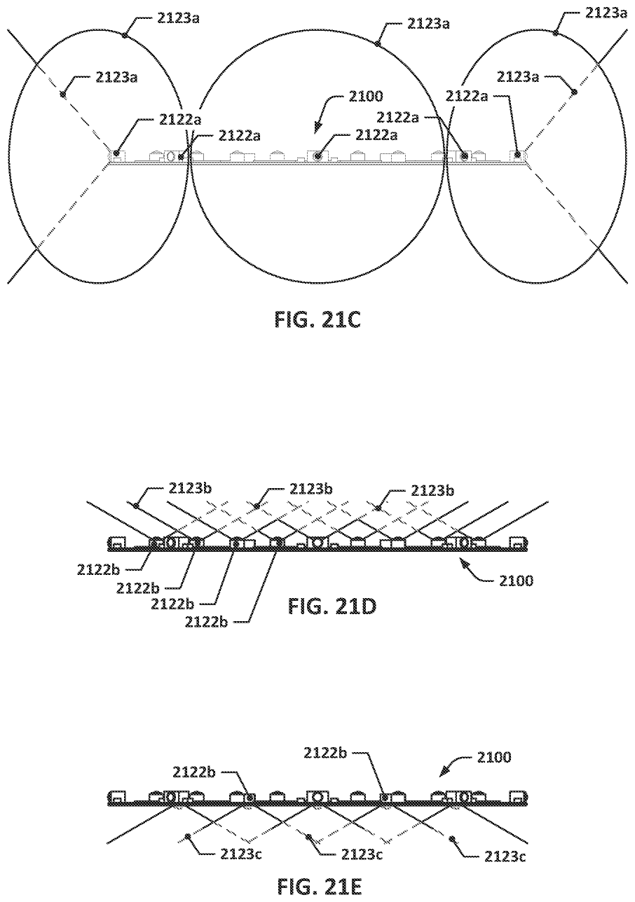

As noted above, sensor-equipped wafers may include different sets of sensors, e.g., multiple sets of optical sensors arranged for imaging different parts of a semiconductor processing chamber. FIGS. 21A through 21E depict views of a sensor-equipped wafer with multiple different sets of optical sensors.

FIGS. 21A and 21B depict isometric views of the top and bottom, respectively, of a sensor-equipped wafer 2100. The sensor-equipped wafer 2100 may include a substrate 2102 that may support a plurality of different sets of optical sensors 2122, e.g., imaging sensors. For example, a first set of optical sensors 2122a may be arranged around the outer periphery of the substrate 2102 and oriented such that their fields of view 2123a (see FIG. 21C) are oriented radially outward from the center axis of the substrate 2102. Such optical sensors 2122a may be used to obtain optical data regarding visible characteristics of the interior walls of the semiconductor chamber in which the sensor-equipped wafer 2100 is to be used. A first set of illumination devices 2124a may be optionally provided adjacent to the optical sensors 2122a, e.g., LEDs positioned on either side of each optical sensor 2122a and oriented to direct light radially outward. Such illumination devices 2124a may allow for illumination of the surface(s) to be imaged.

A second set of optical sensors 2122b may be provided distributed across the top surface of the substrate 2102. The optical sensors 2122b may be oriented such that their fields of view 2123b (see FIG. 21D) are able to obtain optical data from locations directly above the sensor-equipped wafer 2100, e.g., a showerhead underside. A second set of illumination devices 2124b may be optionally distributed across the substrate 2102 as well to direct light vertically upward, e.g., towards the showerhead that may be imaged using the optical sensors 2122b.

A third set of optical sensors 2122c may be provided distributed across the top surface of the substrate 2102, but with their fields of view 2123c (see FIG. 21E) oriented vertically downward, e.g., through apertures formed in the substrate 2102. Such optical sensors 2122c may be used to image, for example, locations beneath the sensor-equipped wafer, e.g., a wafer pedestal. It will be appreciated that additional illumination sources may be provided as well to direct light vertically downwards, if desired.

Such a sensor-equipped wafer 2100 demonstrates that it is feasible to equip a sensor-equipped wafer with a large number of different sensors arranged in different orientations and located in different regions to allow for sensor coverage that may extend both above and below, as well as peripherally around, the sensor-equipped wafer, thereby allowing data to be collected from nearly any location within a semiconductor processing chamber or tool using the sensor-equipped wafer.

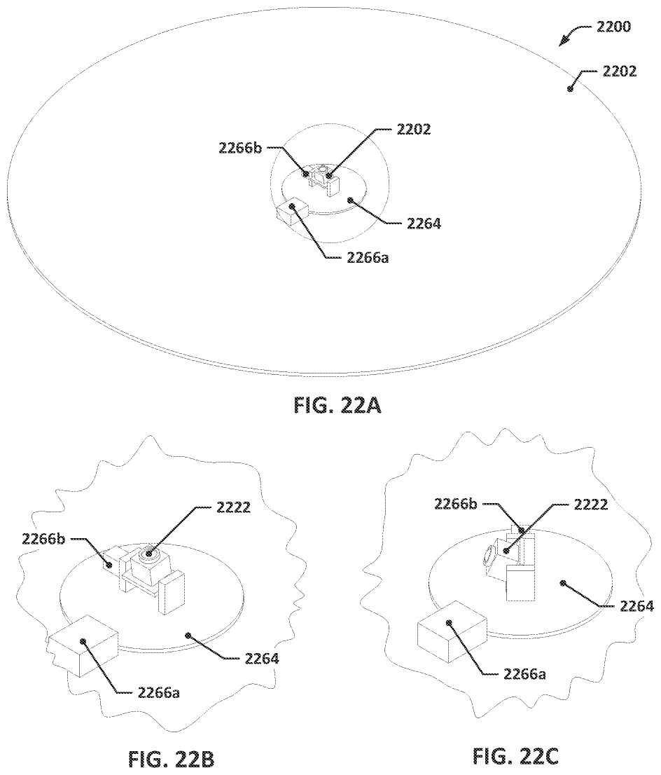

Another example of an example sensor-equipped wafer is shown in FIGS. 22A through 22C, which depict an isometric view and two detail views of a sensor-equipped wafer with a steerable optical sensor. As seen in FIG. 22A, a sensor-equipped wafer 2200 may be provided that has a support structure 2264 that is rotatably supported relative to a substrate 2202. The support structure 2264 may, for example, be rotatably driven by a first rotational drive 2266a such that the support structure 2264 may be caused to rotate about an axis perpendicular to the substrate 2202. The support structure 2264 may support an optical sensor 2222 that is mounted to a rotatable shaft that may be caused to rotate about an axis parallel to the substrate 2202 by a second rotational drive 2266b. Such an arrangement may be used to allow the azimuth and elevation angle of the line of sight of the optical sensor 2222 to be adjusted to allow the optical sensor to be reoriented between any of a number of directions.

Sensor-equipped wafers according to the present disclosure may also, or alternatively, include other types of sensors. For example, in some implementations, a sensor-equipped wafer may include one or more ambient atmospheric sensors, e.g., that measure one or more properties of the ambient atmosphere surrounding the sensor-equipped wafer. In the context of this disclosure, ambient atmospheric sensors are to be understood to be limited to gas concentration sensors configured to determine a concentration of at least a non-water, gaseous component of the ambient atmosphere, e.g., partial pressure sensors that are configured to measure the partial pressure of a non-water gaseous component in the ambient atmosphere, or to airflow sensors configured to measure a velocity of gas flow past such airflow sensors. It will be further understood that an ambient atmospheric sensor, as referred to herein, may also refer to a sensor that is configured to obtain a measurement of water concentration, e.g., a partial pressure of water in addition to obtaining a concentration measurement of at least one gas component other than water, e.g., a partial pressure of oxygen. Detection of gas concentrations of an atmospheric constituent of the ambient air (other than water) surrounding a semiconductor processing tool may allow, for example, for leak detection to be performed using such gas concentration sensors (as discussed in more detail below). The presence of water within a semiconductor processing chamber is generally not a good metric for leak detection since there may be many factors that contribute to the presence of water in a semiconductor processing chamber other than leakage of atmospheric air into the chamber.

In some implementations, the ambient atmospheric sensor(s) may be configured to obtain such measurements in ambient atmospheric conditions that are, for example, in the high vacuum to rough vacuum range of pressures, e.g., such as may be found within a semiconductor processing chamber during some semiconductor processing operations (e.g., in the 40 mTorr to 550 mTorr range or lower). An example of a sensor technology that may be used to obtain such measurements is an adsorption/desorption-based sensor technology, e.g., a substrate, such as a gallium-nitride based substrate, that is selectively absorptive of a particular gas species, e.g., oxygen, and that has an electrical property, such as resistance, that varies based on the amount of that gas that has been adsorbed by the substrate. Such a substrate may also desorb that gas species when exposed to light, with the rate of gas desorption being proportionate to the intensity of the light to which the substrate is exposed, e.g., from an illumination source configured to illuminate the substrate. When the resistance across the substrate is at a steady state, this indicates that the rates of adsorption and desorption are balanced. Thus, by measuring the resistance through such a substrate and then adjusting the intensity of light that is emitted from the illumination source and directed at the substrate until the resistance is balanced, it is possible to obtain a light intensity level that corresponds with a state in which the adsorption and desorption rates are balanced. This intensity level will be proportionate to the partial pressure, and thus the gas concentration, of the gas being adsorbed and may thus serve as a measurement of gas concentration. Such sensors may be quite compact, e.g., fitting within a 25 mm by 10 mm by 10 mm volume, for example. Other suitable sensor types may be used for this purpose as well, of course, and this disclosure is not to be viewed as being limited to this particular example type of gas concentration sensor. It will be understood that while the example ambient atmospheric sensor discussed above integrates multiple different sensor types into a single, integrated, chip-based package, other implementations may use discrete sensor devices, e.g., each mounted separately to a substrate, to provide similar functionality.

One or more such ambient atmospheric sensors may, in some implementations, be included on a sensor-equipped wafer in order to provide a mobile platform that may be positioned in various locations within a semiconductor processing tool in order to evaluate atmospheric conditions at such locations. This allows, for example, atmospheric conditions to be evaluated within each semiconductor processing chamber of a multi-chamber semiconductor processing tool, as well as the atmospheric conditions within, for example, a transfer chamber and/or a load lock of that semiconductor processing tool.

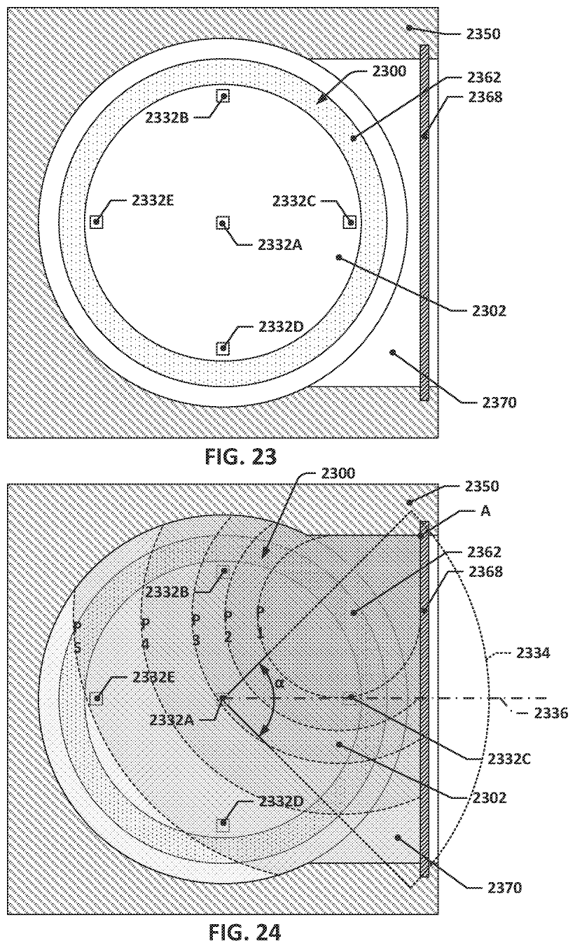

In some implementations, such sensor-equipped wafers may include multiple ambient atmospheric sensors that are arranged at different locations on the surface of the sensor-equipped wafer's substrate. FIG. 23 depicts an example of a sensor-equipped wafer 2300 that has a substrate 2302 that supports a plurality of ambient atmospheric sensors 2332A-E, which may be collectively referred to herein as ambient atmospheric sensors 2332. The sensor-equipped wafer 2300 is shown positioned on a pedestal 2362 within a semiconductor processing chamber 2350; a slit valve 2368 is shown which may be moved up or down to seal or unseal a wafer transit passage 2370 that leads to the interior of the semiconductor processing chamber 2350. The ambient atmospheric sensors 2332 may, for example, be ambient atmospheric sensors that are configured to obtain partial pressure measurements of oxygen and water vapor that are in the ambient atmosphere surrounding each ambient atmospheric sensor 2332.

If multiple ambient atmospheric sensors 2332 are utilized, as shown in FIG. 23, such ambient atmospheric sensors 2332 may be positioned at spaced-apart locations on the substrate 2302. For example, in FIG. 23, there are five ambient atmospheric sensors 2332—one that is located at the center of the substrate 2302 and the others at locations proximate the outer edge of the substrate 2302 and spaced 90° apart from one another. If multiple ambient atmospheric sensors are positioned at different locations, e.g., as shown in FIG. 23, this allows for partial pressure measurements of oxygen (and, optionally, water) to be simultaneously, or near-simultaneously, taken at different locations. Such measurements may then be used to a) obtain a more accurate evaluation of whether the ambient atmospheric conditions are within acceptable bounds at more than, for example, a single location relative to the substrate 2302, and b) determine the direction in which a potential leak may be located.

Semiconductor processing chambers typically operate at sub-atmospheric conditions. Such chambers are typically machined out of a large block of metal, e.g., aluminum, in order to provide a sealed environment. Various openings and apertures in such a component are sealed with vacuum-rated seals in order to prevent gas leaks from the external ambient environment, e.g., atmospheric air, into the interior of the semiconductor processing chamber. Such leaks may cause pressure increases and/or may introduce contaminants (e.g., oxygen, etc.) that may negatively impact semiconductor processing operations performed within the semiconductor processing chamber. The concentration of such contaminants, and thus the partial pressures attributable to those contaminants are generally highest at the point(s) at which such contaminants are introduced into the semiconductor processing chamber, i.e., at the locations where leaks may exist, and then decrease with increasing distance from the leak point.

For clarity, it will be noted that a “leak,” in the context of this disclosure, is to be understood to refer to a location in a semiconductor processing chamber at which the amount of gas that leaks into the semiconductor processing chamber from the ambient external atmosphere when the semiconductor processing chamber is at a designated sub-atmospheric pressure exceeds a predetermined threshold. Sensor-equipped wafers such as the sensor-equipped wafer 2300 may, for example, be able to determine when and where the level (e.g., concentration and/or partial pressure) of a particular component, e.g., oxygen, of ambient atmospheric air is above a particular threshold.

For a sensor-equipped wafer such as the sensor-equipped wafer 2300, partial pressure measurements of oxygen may be obtained using the ambient atmospheric sensors 2332. Such measurements may then be used to determine an approximate direction, relative to the sensor-equipped wafer 2300, along which the leak location is likely to lie. For example, FIG. 24 depicts the semiconductor processing chamber 2350 of FIG. 23 but with different partial pressure levels of a gas, e.g., oxygen, indicated with different shaded regions separated by dashed lines. The depicted partial pressure levels (with P₁ through P₅ representing decreasing pressures) are representative of partial pressure levels that would generally arise, for example, if there was a leak point in the seal for the slit valve 2368 at location A. Generally speaking, ambient atmospheric sensors that measure partial pressure levels, e.g., of oxygen, that are at higher levels compared to the partial pressure levels of such a gas simultaneously measured by other ambient atmospheric sensors on the sensor-equipped wafer 2300 will be physically closer to the leak that is the source of the gas in question than those other ambient atmospheric sensors. Generally speaking, the more ambient atmospheric sensors 2332 that are distributed across a sensor-equipped wafer or along its outer perimeter, the higher the accuracy with which the location of leaks may be determined using the sensor-equipped wafer 2300.

As can be seen, of the five ambient atmospheric sensors 2332, the ambient atmospheric sensor 2332C would measure the highest partial pressure of oxygen of P₁, with the next highest partial pressure of oxygen (just under P₂) being measured at ambient atmospheric sensor 2332B. Such information may be used to determine at least the sector of the sensor-equipped wafer that is closest to a potential leak, e.g., the location of such a leak may be generally determined to be within a circular sector 2334 of a degrees of arc extending outward from the center of the sensor-equipped wafer 2300 and having a centerline 2336 passing through the ambient atmospheric sensor 2332 having the highest oxygen partial pressure reading (ambient atmospheric sensor 2332C, in this case). In the case of a sensor-equipped wafer 2300 with ambient atmospheric sensors that are evenly spaced about the periphery of the sensor-equipped wafer 2300, the angle α may be equal to 360° divided by the number of ambient atmospheric sensors 2332 that are located along the periphery of the sensor-equipped wafer 2300. In the depicted example, a equals 90°, and the highest oxygen partial pressure reading at the ambient atmospheric sensor 2332C thus indicates that the leak is radially outward from the right-most quadrant (with respect to the Figure orientation) of the sensor-equipped wafer 2300. The potential leak location may, in some cases, be resolved with additional granularity by considering data from other ambient atmospheric sensors 2332 on the sensor-equipped wafer 2300. For example, the two ambient atmospheric sensors 2332B and 2332A, which are measuring partial pressure readings in this example of, for the ambient atmospheric sensor 2332B, just under P₂ and, for the ambient atmospheric sensor 2332A, approximately P₃. In contrast, the ambient atmospheric sensor 2332D indicates a partial pressure reading of less than P₄. Thus, the elevated partial pressure measurement of ambient atmospheric sensor 2332B compared to the lower partial pressure measurement of ambient atmospheric sensor 2332D indicates that the leak location “A” is on the side of the centerline 2336 closer to the ambient atmospheric sensor 2332B, thereby allowing the location of the leak “A” to be further narrowed to a location radially outward from the octant of the sensor-equipped wafer 2300 that is above (with respect to the Figure orientation) the centerline 2336.

Generally speaking, a good approximation of where a potential leak or potential leaks may exist may be determined by identifying localized peaks in partial pressure readings, e.g., where an ambient atmospheric sensor 2332 reports a partial pressure reading that is higher than the partial pressure readings reported by circumferentially adjacent ambient atmospheric sensors 2332. This may generally indicate that a leak exists at a location radially outward from the sensor-equipped wafer and in between radii extending outward from the wafer center and along axes that are midway between the ambient atmospheric sensor 2332 that reports the localized peak and the circumferentially adjacent ambient atmospheric sensors 2332. The location of that leak may be further refined, e.g., to one side or the other of the ambient atmospheric sensor 2332 that reports the localized peak partial pressure, based on which of the ambient atmospheric sensors 2332 circumferentially adjacent to the ambient atmospheric sensor 2332 that reports the localized peak partial pressure reports a higher partial pressure.

It will be understood that while the above examples have featured ambient atmospheric sensors that measure the partial pressure of oxygen, similar techniques may be practiced using partial pressure sensors that measure the partial pressure of other gases that may be present within ambient atmospheric air, e.g., nitrogen (N₂), argon (Ar), carbon dioxide (CO₂), and neon (Ne). It will also be understood that other types of gas concentration sensors (other than partial pressure sensors) may be used in place of, or in addition to, the partial pressure sensors discussed above. It will also be understood that during such measurements, the gas for which the partial pressure is being sought may be prevented from otherwise flowing into the semiconductor processing chamber, e.g., if the semiconductor processing tool is configured to supply oxygen gas to the semiconductor processing chamber during some stages of normal semiconductor processing operations, such deliberate oxygen delivery during leak testing may be prevented such that the only potential sources of oxygen (or other gases detectable by the ambient atmospheric sensors) are leaks at one or more locations within the semiconductor processing chamber.

Such semiconductor processing chambers may also include exhaust systems that may be used to evacuate processing gases that are introduced during semiconductor processing operations and to maintain a desired vacuum level within the semiconductor processing chambers. During leak testing, it may also be desirable to temporarily deactivate such exhaust systems to avoid affecting the partial pressure levels of contaminants within the semiconductor processing chamber. Thus, for example, the gas concentration measurements discussed above may be conducted within a semiconductor processing chamber using the sensor-equipped wafer 2300 (or one similar thereto) while the interior atmosphere of the semiconductor processing chamber is unperturbed by incoming (aside from any potential leaks, of course) or outgoing gas flows, movements of components within the interior of the semiconductor processing chamber (e.g., elevational changes of a pedestal and/or showerhead), opening and/or closing operations of valves and/or doors, or activation of systems such as turbopumps or cryopumps. By conducting such measurements in a “still” internal ambient atmosphere, potential sources of partial pressure variations other than potential leak points may be minimized or eliminated, thereby increasing the likelihood of accurately detecting such leaks and of identifying where such leaks may be located.

It will be further appreciated that some implementations of sensor-equipped wafers may feature gas concentration sensors that may be configured to obtain readings of gases other than gases typically found in atmospheric air, e.g., gases that may be used in semiconductor processing operations, that may be byproducts of such processing operations, and/or that may be introduced into the processing chamber from other locations within the tool, e.g., from other processing chambers within the tool (for example, that may accompany a wafer that is transferred into a chamber from another chamber within the tool). For example, in some implementations, a sensor-equipped wafer may feature one or more gas concentration sensors that are configured to detect concentrations of hydrogen species (Hₓ), ozone (O₃), nitrogen oxides (NOₓ), chlorofluorocarbons (CFCs), methane (CH₄), and/or volatile organic compounds (VOCs). Such chemical species may, for example, outgas from materials that are deposited on wafers within a processing chamber. Such material may also deposit on surfaces of the processing chamber and therefore remain in the processing chamber even after the wafer or wafers being processed are removed. Material that remains in the processing chamber after wafer removal may, for example, outgas or react with other gases within the processing chamber to produce gas species that may, if concentrations thereof exceed a particular threshold, be considered to be sufficiently detrimental to processing operations to be performed in such a processing chamber to warrant taking corrective action, e.g., subjecting the chamber to a cleaning process or removing the chamber from the tool and replacing it with a new one.

In some implementations, a sensor-equipped wafer may include a particulate sensor, e.g., such as an ionization or photoelectric particulate sensor (similar, for example, to the sensors used in smoke detectors to detect smoke particulates—although potentially more sensitive). In ionization detectors, a small sample of radioactive material is provided that ionizes or electrically charges gas molecules of the atmosphere being sensed that are present between two metal plates, e.g., electrodes, within a sample chamber that is in fluidic communication with the atmosphere being monitored. When solid particles, e.g., particulates, flow through the chamber, they attract the ionized species and carry them away, thereby reducing the current that flows between the two electrodes. The amount of current reduction provides a measure of the amount of particulates that may be present. In photoelectric particulate detectors, a light source may be configured to direct a beam of light such that the beam of light passes by a photodetector associated with the light source without striking it, e.g., the beam of light crosses in front of, and parallel to, the photo-sensitive surface of the photodetector but is not incident on it. When particulates are present in the atmosphere in front of the photodetector, however, some of the light rays that would ordinarily pass by the photodetector instead strike the particulates and are scattered off of them, resulting in some scattered light striking the photodetector. The amount of such light that strikes the photodetector provides a measure of the concentration of particulates within the atmosphere.

Sensor-equipped wafers with one or more particulate sensors may be used to detect the presence of particulate contaminants within a semiconductor processing chamber. Such particulates may, for example, result from mechanical abrasion between moving components within the processing chamber, e.g., lift pins and/or pedestals moving up and down, wafer-handling robot movements within the chamber, showerhead movements within the chamber, etc., or may be the byproduct of semiconductor processing operations, e.g., deposition materials that may have deposited on surfaces of the semiconductor processing chamber and which may have detached from such surfaces, e.g., through flaking.

It will be appreciated that techniques similar to those discussed above for sensor-equipped wafers with atmospheric gas concentration sensors, e.g., for leak detection, may also be used with gas concentration sensors configured to detect gas species not normally found in atmospheric air, although for a somewhat different purpose. For leak detection, the gases being detected originate within the processing chamber via leak paths from the ambient atmosphere around the tool. For sensor-equipped wafers having gas concentration sensors configured to detect gases other than those that are in atmospheric air, the gases being detected may originate within the processing chamber by virtue of outgassing or other mechanism. Thus, a technique for detecting the potential location of a leak point using a gas concentration sensor configured to detect oxygen may similarly be used with a gas concentration sensor configured to detect, for example, a CFC that is outgassed from a deposited film within the processing chamber. Instead of indicating a potential leak detection point, such a technique may instead indicate the region or regions of the chamber in which such a deposited film is present in the greatest concentration. Similarly, such techniques may also be practiced with particulate sensors to similar effect, e.g., to detect a region or regions of the processing chamber that generate the greatest concentration of particulates.

Some implementations of sensor-equipped wafers may have one or more gas concentration sensors and/or one or more particulate sensors (potentially in addition to other sensors discussed herein). In some implementations, such a sensor-equipped wafer may include multiple gas concentration sensors configured to detect the same species of gas (e.g., to be used to facilitate determining the location of a leak or the location of a region of the chamber generating the greatest amount of outgassing). In some other or additional such implementations, gas concentration sensors or sets of gas concentration sensors for detecting different species of gas may be located on common sensor-equipped wafer. For example, a sensor-equipped wafer may have one set of gas concentration sensors for detecting oxygen (for leak detection) and another set of gas concentration sensors for detecting CFCs (for detecting the location of outgassing from deposition byproducts on chamber surfaces).

In semiconductor processing tools in which such sensor-equipped wafers may be used, a controller of the semiconductor processing tool may be configured to move such a sensor-equipped wafer between different locations, e.g., between a storage or loading location and a semiconductor processing chamber of the semiconductor processing tool. The semiconductor processing tool controller may be further configured to send a command or commands to the sensor-equipped wafer, e.g., via a wireless communications link, to cause the controller of the sensor-equipped wafer to cause one or more sensor readings to be obtained via the ambient atmospheric sensors thereof. For example, concentration or partial pressure measurements of a particular component, e.g., oxygen, of the gas within the semiconductor processing chamber and around the sensor-equipped wafer may be caused to be obtained. The semiconductor processing tool controller may also cause various other operations to be performed prior to causing such measurements to be obtained.

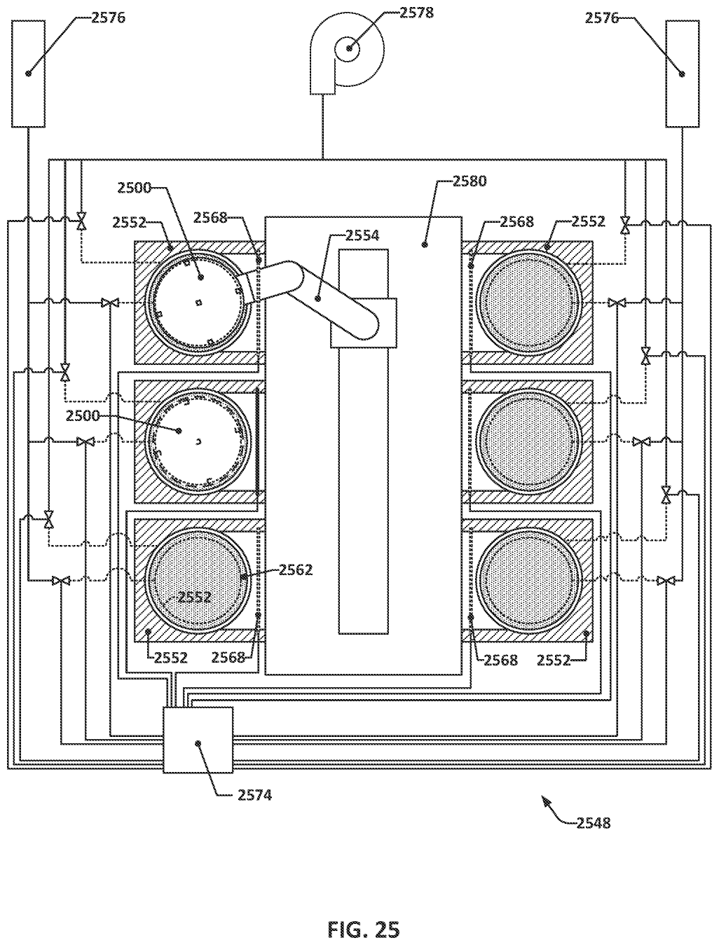

FIG. 25 depicts an example semiconductor processing tool (or a portion thereof) that may be configured to utilize a sensor-equipped wafer similar to that discussed above with respect to FIGS. 23 and 24. As can be seen in FIG. 25, a semiconductor processing tool 2548 is shown that has a vacuum transfer module 2580 with six semiconductor processing chambers 2552 connected thereto. A wafer-handling robot 2554 may be located within the vacuum transfer module 2580 and may be configured to be able to move wafers in between the various semiconductor processing chambers 2552 (not shown are, for example, load locks that may be used to transfer wafers into and out of the vacuum transfer module 2580 from, for example, an EFEM).

Each semiconductor processing chamber 2552 may have a pedestal 2562 and a showerhead 2553 located within it. The pedestal may be configured to flow gases provided by one or more gas sources 2576 when one or more valves (represented by the double-end-to-end-triangle symbols) controlled by a controller 2574 are caused to open, e.g., during semiconductor processing operations. Each semiconductor processing chamber 2552 may also include a door 2568 that may be controlled by the controller 2574 so as to transition between open and closed states, thereby allowing the semiconductor processing chamber 2552 to be sealed, for example, during wafer processing operations and unsealed to allow wafers to be passed into or out of the semiconductor processing chamber 2552. The semiconductor processing tool 2548 may also have, or be connected with, a vacuum pump 2578 that may be fluidically connected with each semiconductor processing chamber 2552 so as to be able to exhaust processing gases from the semiconductor processing chambers 2552. The exhaust flow from each semiconductor processing chamber 2552 may be adjusted by way of a corresponding valve that is controlled by the controller 2574, e.g., to allow the exhaust for each semiconductor processing chamber 2552 to be throttled up or down, as needed, or even stopped completely.

As can be seen, the controller 2574 may be caused, e.g., via computer-executable instructions stored in a memory device, to control the wafer-handling robot 2554 so as to place a sensor-equipped wafer 2500 into one of the semiconductor processing chambers 2552 (in this case as shown in the upper left semiconductor processing chamber 2552). The controller 2574 may then cause the wafer-handling robot 2554 to withdraw from the semiconductor processing chamber 2552, leaving the sensor-equipped wafer 2500 in place on the pedestal 2562, as shown in a dashed outline in the middle-left semiconductor processing chamber 2552. Once the wafer-handling robot 2554 has been withdrawn from the semiconductor processing chamber 2552, the controller 2574 may cause the flow of gas to that semiconductor processing chamber 2552 from the one or more gas sources 2576 to stop, e.g., by controlling one or more valves to transition to a closed state, and may cause the chamber door 2568 to transition to a sealed state (shown in the left-middle semiconductor processing chamber 2552 by way of the door 2568 for that chamber being shaded black). The controller 2574 may then send a command or commands to the sensor-equipped wafer 2500 to cause the sensor-equipped wafer 2500 to obtain one or more sensor readings from one or more ambient atmospheric sensors located thereupon (indicated by the five small squares in sensor-equipped wafer 2500). The data from the sensor readings may then be stored, e.g., in memory on the sensor-equipped wafer and/or transmitted to the controller 2574 for further processing.

The controller 2574 and/or the controller of the sensor-equipped wafer may, for example, determine a) if there is a potential leak (based on the peak concentration or partial pressure for a particular component, e.g., oxygen, of ambient atmospheric air within the semiconductor processing chamber being above a predetermined threshold level) and, in some cases, b) the potential location(s) of such a leak or leaks, as discussed above.

In some alternative or additional implementations, the ambient atmospheric sensor(s) used may include ambient atmospheric sensors that are configured to obtain measurements in non-vacuum ambient atmospheric conditions, e.g., at pressures of one atmosphere or nearly one atmosphere, e.g., as may be found in an equipment front end module (EFEM), front-opening unified pod (FOUP), or other piece of equipment that houses semiconductor wafers either within a semiconductor processing tool or during transit between semiconductor processing tools or other equipment.

In such implementations, the ambient atmospheric sensors that are used may include one or more different types of sensors, including, but not limited to, relative humidity sensors, oxygen level sensors, temperature sensors, and airflow sensors (e.g., anemometers). Sensor-equipped wafers equipped with one or more such sensors may, for example, be used to evaluate and/or characterize different aspects of equipment that operates at atmospheric conditions. For example, while the atmosphere within an EFEM is generally kept at atmospheric or near-atmospheric pressure levels, the atmosphere within such an EFEM may, in some cases, be pretreated so as to have a specified humidity level and/or temperature. In some cases, an EFEM may have an atmosphere that is markedly different in composition than ambient atmospheric air, e.g., an EFEM may be supplied with an atmosphere in which most or all oxygen has been removed and/or in which nitrogen is present either exclusively or in much greater concentration as compared with the concentration of nitrogen in the atmosphere.

Ambient atmospheric sensors that measure humidity, temperature, and/or gas concentration may thus be used to evaluate what the actual humidity levels, temperature levels, and/or gas concentration within such an EFEM may be. Such measurements may then be compared against target values to determine if the EFEM has the desired internal environment. It will be understood that such measurements may similarly be obtained by such a sensor-equipped wafer in other environments as well, e.g., within a wafer storage buffer, within a FOUP, within a wafer cassette, etc.

As noted above, some sensor-equipped wafers may be equipped with one or more airflow sensors to allow measurements of the velocity of air (or other gas or gas mixture) across the sensor-equipped wafer to be obtained. Such measurements may, for example, allow for an evaluation to be made as to the effectiveness of various airflow systems within an EFEM, FOUP, buffer, or other system to be made (with “airflow” understood to be inclusive of systems that may operate with gases other than air, e.g., nitrogen). For example, in some buffers and/or FOUPs, an inert gas, such as nitrogen, may be introduced into such structures, and then exhausted therefrom, in a manner that would cause a certain minimum amount of gas flow to occur above each wafer that may be placed therein. For example, a buffer may feature a set of 25 shelves arranged in a vertical stack with 10 mm of spacing between each pair of shelves. Each shelf may be used to temporarily support a wafer while the wafer is occupying the buffer. The buffer may have gas inlets that direct an inert gas, such as nitrogen, into the buffer such that at least some of the inert gas flows over the top of each wafer that is loaded into the buffer (when the buffer is full). In such a buffer, it may be desirable to have a specified minimum level of inert gas flow above each wafer, regardless of what position that wafer is in. A sensor-equipped wafer equipped with airflow sensors, such as is discussed above, may be placed in different wafer positions within such a buffer and the airflow sensors used to obtain a direct measurement of the amount of gas flow that occurs above a wafer that may be placed in each of those positions.

Such airflow sensors may, for example, include anemometers, e.g., hot-wire anemometers. Such sensors are available in small form factors suitable for use on sensor-equipped wafers. For example, low-profile surface-mount microelectromechanical systems (MEMS)-based air velocity sensors that have thicknesses of only a few millimeters, e.g., 4 millimeters or less, may be used. Such sensors may operate like a hot-wire anemometer in which air flowing past a wire carrying an electrical current. As the air cools the wire, this changes the resistance of the wire in a way that corresponds with the air flow speed past the wire. Such sensors are suitable for use on a sensor-equipped wafer that may, for example, need to maintain an overall maximum thickness of 5 mm or less in order to be transportable within a semiconductor processing tool without violating clearance requirements for semiconductor wafers.

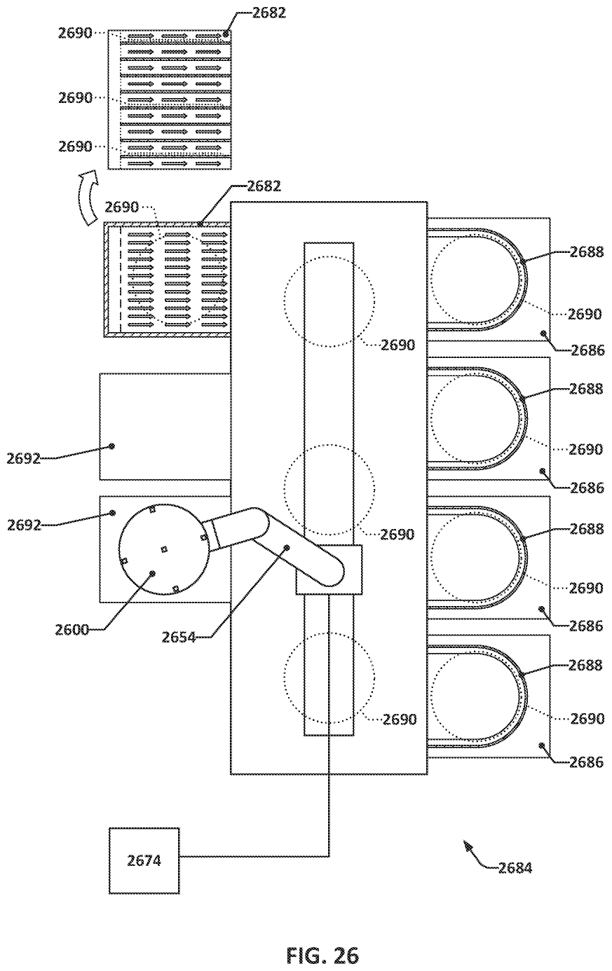

FIG. 26 depicts a schematic of a portion of a semiconductor processing tool. In FIG. 26, an EFEM 2684 is shown. The EFEM 2684 may have a plurality of load ports 2686 connected thereto, each of which may receive a FOUP 2688 that may contain, or receive, wafers to be processed or processed in the semiconductor processing tool. The EFEM 2684 may have a wafer-handling robot 2654 located within it that is configured to move wafers between the FOUPs 2688, load locks 2692, and/or a buffer 2682. A controller 2674 may control the wafer-handling robot 2654 and various other systems of the EFEM 2684, e.g., FOUP doors, load-lock doors, etc.

The buffer 2682, for example, may have a plurality of wafer storage locations arranged in a stacked configuration (as shown in the side view of the buffer 2682 shown in the upper left corner of FIG. 26). In some instances, the buffer 2682 may have a pressurized plenum that introduces gas, e.g., nitrogen or other gas that is non-reactive with the wafers loaded therein, into the buffer such that the gas then flows across the wafers that are stored therein, e.g., along the paths indicated by the arrows within the buffer 2682.

The controller 2674 in such a semiconductor processing tool may cause the wafer-handling robot 2654 to move a sensor-equipped wafer 2600 between the various locations 2690 and, with the sensor-equipped wafer 2600 positioned at each location 2690, transmit one or more commands to the sensor-equipped wafer 2600 to cause the sensor-equipped wafer 2600 to obtain sensor readings, e.g., airflow readings, from one or more ambient atmospheric sensors located thereupon. Such readings may be stored on the sensor-equipped wafer, e.g., in memory located on the sensor-equipped wafer, or transmitted to the controller 2674.

In some implementations, sensor-equipped wafers may include one or more sound sensors (e.g., audio sensor or microphone) that may be used to collect audio data from both the surrounding environment or from the sensor-equipped wafer itself. In some embodiments, the one or more sound sensors may have a capacitive microphone, peak detector, and an amplifier. For example, if the wafer-handling robot that is transporting a sensor-equipped wafer having one or more microphones has a bearing that is starting to degrade, this may cause small vibrations in the end effector of the wafer-handling robot that are then transmitted to the sensor-equipped wafer. Such vibrations may generate audible noise artifacts, i.e., sound wave signals that may have characteristic frequency spectra and/or signal strengths, that are transmitted through the structure of the sensor-equipped wafer itself, e.g., the sensor-equipped wafer may vibrate such that a portion thereof repeatedly lifts off of a supporting feature of an end effector and then falls back onto the supporting feature, resulting in a series of rapid contact events between the sensor-equipped wafer and the supporting feature, with each contact event resulting in an acoustic pulse that is transmitted through the structure of the sensor-equipped wafer and is then detected by the microphone(s) mounted thereto. Such acoustic signals may, for example, have frequencies in the 20 Hz to 20,000 Hz range.

Such microphone-equipped wafers may also be used to detect acoustic events that result in sound waves reaching the microphones via atmospheric transmission (as opposed to via acoustic propagation through solid material). For example, equipment that is starting to fail or that has experienced excessive wear may generate sounds that are detectable by such a microphone-equipped wafer, allowing for potential detection of such issues within a processing chamber or vacuum transfer chamber. In some sensor-equipped wafers, multiple microphones may be used and placed at different locations, e.g., similar to the arrangement of gas concentration sensors discussed with respect to FIG. 23, to allow the location of the source of detected acoustic events relative to the sensor-equipped wafer to be determined, similar to how leaks may be detected using gas concentration sensors. This may allow, for example, a sensor-equipped wafer having microphones to be used to not only detect acoustic events that may indicate a potential component failure, but also determine the general location of where the acoustic event originated, which may assist with identifying which component is the source of the acoustic event (and which may thus need replacement or service).

Generally speaking, acoustic data from a microphone sensor will provide time-domain data indicating acoustic signal strength at any given instant in time. However, such acoustic data may represent a plurality of different sources of acoustic signals that combine together and are received simultaneously by the microphone sensor as a single, blended acoustic signal. Such acoustic data may be subjected, for example, to various types of post-processing in order to provide data that is better tailored for various analytic techniques.

For example, an analog signal from a microphone sensor may be converted to a digital representation using analog-to-digital conversion. Digitized data from successive time intervals may then be processed using a fast Fourier transform to obtain frequency-domain data from which the power spectral density over the time interval may be determined. The power spectral density provides information relating to the signal strength in different frequency bins. Such information, as discussed below, may be used in both characterizing the potential source of such acoustic signals and in determining the potential location of acoustic signals.

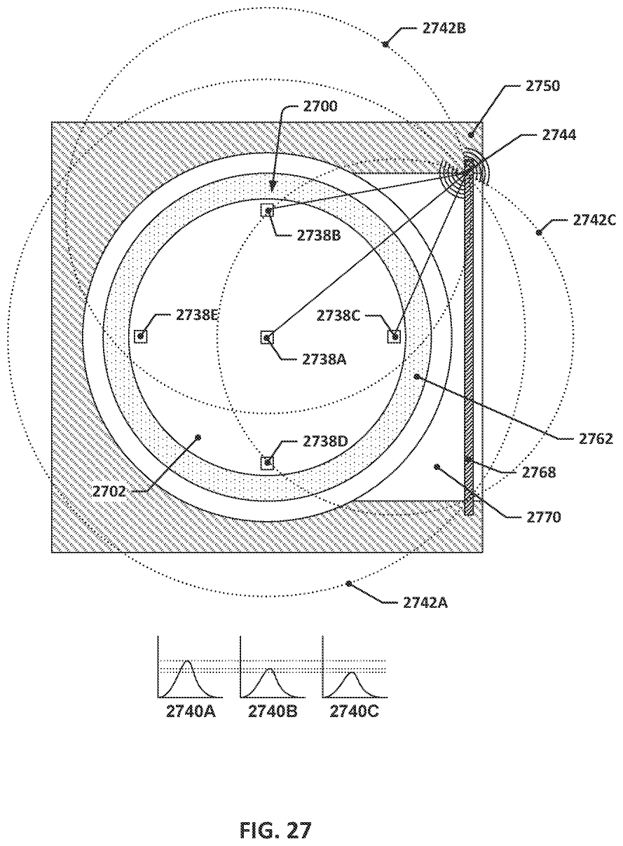

FIG. 27 depicts an example of a sensor-equipped wafer 2700 that includes a plurality of microphone sensors 2738, e.g., microphone sensors 2738A-E. The sensor-equipped wafer 2700 is shown, in FIG. 27, seated on a pedestal 2762 within a chamber 2750. The chamber 2750 may include a wafer transit passage 2770 through which the sensor-equipped wafer 2700 may be inserted into the chamber 2750 or removed from the chamber 2750.

The microphone sensors 2738A-E are, in this example, omnidirectional microphone sensors that are arranged in a distributed fashion across a substrate 2702. As shown, the microphone sensors 2738A-E are arranged in a cross-shaped pattern, with one microphone sensor 2738A located at the center of the substrate 2702 and the four remaining microphone sensors 2738B-E positioned in a circular, evenly-spaced array at the edge of the substrate 2702. It will be understood that more or fewer microphone sensors 2738 may be used, e.g., as few as three microphone sensors 2738 may be used to determine a direction from which a particular sound is emanating via triangulation based on the timing of when the same acoustic signal is detected by each separate microphone sensor 2738 and/or via trilateration based on the signal strengths measured by each microphone sensor in response to the same acoustic event. In either case, the signal detected by each microphone sensor may be used as an analog for distance between the source of the acoustic event being detected and that microphone sensor.

In trilateration, the intensity or signal strength of the acoustic signal detected by each microphone sensor may serve as an indication of distance between each microphone sensor and the source of the acoustic event of interest. In triangulation, the differences in timing between receipt of the same acoustic signal by the microphone sensors may serve as an indication of relative distance from each microphone sensor to the source of an acoustic event. In triangulation, the distance analog may take the form of scalable component (represented by the differences in timing between receipt of the acoustic event signal between the microphone sensors) that is added to a constant component (which would be the same for all signals—this represents the shortest distance between any of the microphone sensors and the source of the acoustic event, i.e., the distance between the acoustic event source and the microphone sensor closest thereto). It will be understood that in the case of either triangulation or trilateration, the signal that is evaluated (either in terms of signal strength or timing of receipt) may actually be a sub-portion of the acoustic signal, e.g., a sub-signal of a particular frequency range. For example, after transforming an acoustic signal into the frequency domain via a fast Fourier transform, analysis may indicate that the frequency bin that has the highest signal strength contribution to the overall signal is the 190 Hz to 200 Hz frequency bin. For the purposes of triangulation and/or trilateration techniques, the timing of receipt and/or signal strengths that are obtained and evaluated in each such technique may be determined based on the timing of receipt or signal strength of an acoustic signal component in the 190 Hz to 200 Hz frequency bin.

Each distance analog can be treated as defining the radius of a circle that is centered on the corresponding microphone sensor. In the ideal case in which the distance analog is scaled to match the actual distance between the corresponding microphone sensor and the source of the acoustic event, the circles will all pass through a point that corresponds with the source of the acoustic event (or, accounting for potential measurement error, through a circular region centered on such a point—the size of the circular region may be selected to be commensurate with a desired level of location determination accuracy). Since the positions of the microphone sensors on the substrate relative to each other are known, the location where the acoustic event is relative to the substrate can be determined by adjusting the scaling of the distance analog until a solution can be found for a point (or circular region) where some number, or all, of circles mentioned above intersect; the point of intersection would represent the location of the source relative to the substrate. If the location and orientation of the substrate relative to the process chamber are known, this then allows the location of the acoustic event relative to the chamber to be determined.

The scaling of the distance analog may, for trilateration, involve simply scaling the distance analog (for trilateration) or scaling the scalable component of the distance analog and also varying the constant component of the distance analog (for triangulation).

The concepts discussed above are represented in FIG. 27 by the overlay of three dotted circles 2742A, 2742B, and 2742C centered on the three microphone sensors 2738A, 2738B, and 2738C. Similar circles are not shown for the microphone sensors 2748D and 2738E, but such circles could be added if desired. Also shown in FIG. 27 are acoustic signals 2740A, 2740B, and 2740C detected by the microphone sensors 2738A, 2738B, and 2738C in the same time interval (with time being along the x-axis and signal strength being along the y-axis) in response to an acoustic event occurring at acoustic event location 2744. The acoustic signals 2740A, 2740B, and 2740C can be seen to have differing maximum signal strengths, as evidenced by the horizontal dotted lines that are coincident with the peaks of the acoustic signals 2740A, 2740B, and 2740C.

The circles 2742A, 2742B, and 2742C are shown with radii that are proportionate to the corresponding signal strengths of the acoustic signals 2740A, 2740B, and 2740C. The circles 2742A, 2742B, and 2742C, in this case, have been scaled so as to all intersect at a common point, i.e., the location 2744. Thus, the radii of the circles 2742A, 2742B, and 2742C are representative of the actual distance between each of the microphone sensors 2738A, 2738B, and 2738C and the location 2744. By solving for the location where all three circles 2742A, 2742B, and 2742C meet, the position of the location 2744 relative to the substrate 2702 may be determined, thereby allowing for a subsequent determination of where the location 2744 is relative to the chamber 2750.

Additional microphone sensors 2738 beyond three such microphone sensors 2738 may provide additional acoustic signal data that may be used to additionally refine any signal direction determination performed using data collected by such microphone sensors 2738.

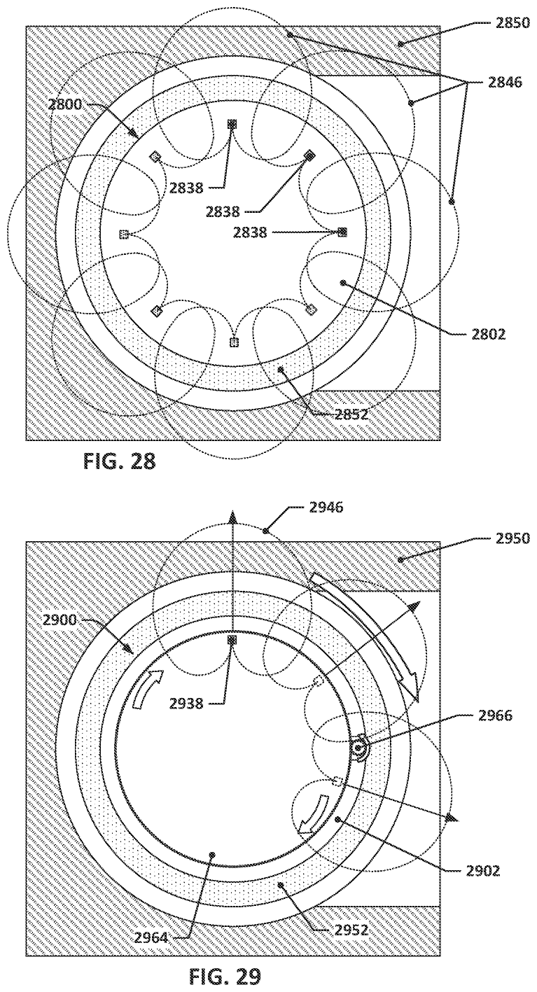

In FIG. 28, another example of a sensor-equipped wafer 2800 is shown. The sensor-equipped wafer 2800 may include a substrate 2802 that supports a plurality of microphone sensors 2838 that are, in this example, directional microphone sensors. Such microphone sensors 2838 may have a directional bias in their sensitivities, e.g., having a sensitivity to acoustic signals that azimuthally varies. In FIG. 28, pickup zones 2846 are shown that represent the relative sensitivity for each microphone sensor 2838 as a function of azimuthal direction relative to the microphone sensor 2838. The farther any portion of the dotted line representing a pickup zone 2846 is from the corresponding microphone sensor 2838, the more sensitive the microphone sensor 2838 is to an acoustic signal originating along a line extending from the microphone sensor 2838 to that portion of the dotted line.

As shown in FIG. 28, the microphone sensors 2838 are arranged in an equally spaced circular array about the outer perimeter of the substrate 2802. Such an arrangement may allow for rapid determination of the azimuthal direction along which an acoustic event occurs, e.g., by identifying the two or three such microphone sensors 2838 that detect the highest-strength signal resulting from an acoustic event. For example, if one microphone sensor detects the highest-strength signal resulting from the acoustic event and the two microphone sensors that flank that sensor detect acoustic signals of equal signal strength, then it can be assumed that the acoustic event occurred at a location that lies along a radius extending outward from the substrate 2802 center and through the microphone sensor 2838 that detected the highest-strength signal. If the two flanking microphone sensors 2838 are not equal in magnitude, then the microphone sensor 2838 of those two flanking microphone sensors 2838 that detects the second-highest signal strength acoustic signal may be used with the highest-strength acoustic signal to determine a ratio that can be applied to the angular spacing between the microphone sensors 2838 to determine what direction the acoustic signal appears to originate from.

For example, in the depicted example, the angular spacing between microphone sensors 2838 is 45°. If the microphone sensor 2838 that is at the 12 o'clock position detects the highest strength signal (S1) of an acoustic event and the microphone sensor 2838 to the right of it detects the second-highest strength signal (S2) of the acoustic event, the azimuthal direction, relative to the center of the substrate 2802, along which the acoustic event location lies may be determined to be in between the two microphone sensors 2838 that recorded the highest signal strengths from the acoustic event and angularly offset by an angle θ from a first radius extending from the center of the substrate 2802 to the center of the microphone sensor that detected the highest signal strength acoustic signal. The angle θ may be determined by multiplying the angle defined between the first radius and a second radius extending from the center of the substrate 2802 to the center of the microphone sensor that detected the second highest signal strength acoustic signal by S1/(S1+S2).

Such a determination may be used to identify the azimuthal angle relative to the substrate 2802 along which the acoustic event originated. A further determination may be made as to the relative orientation of the substrate 2802 relative to the chamber in order to determine the direction, relative to the chamber, along which the acoustic event originated.

FIG. 29 depicts another example sensor-equipped wafer in the context of a processing chamber. As shown in FIG. 29, a sensor-equipped wafer 2900 is supported on a pedestal 2952 of a chamber 2950. The sensor-equipped wafer 2900 includes a substrate 2802 that rotatably supports a support structure 2964. The support structure 2964 may, for example, be caused to rotate by rotational drive 2966. The support structure 2964 may support a microphone sensor 2938; the microphone sensor 2938 may be a directional microphone, similar to the directional microphone sensors 2838 discussed earlier. The dotted line 2946 indicates a pickup zone for the microphone sensor 2938. As can be seen, when the support structure 2964 is caused to rotate, e.g., in a clockwise manner as shown in FIG. 29, the microphone sensor 2938 may be caused to rotate about the rotational center of the support structure 2964, thereby re-orienting the pickup zone such that the axis of maximum sensitivity of the microphone sensor can be changed to any desired angle. This allows the microphone sensor 2938 to be used to azimuthally scan about the circumference of the substrate 2902 for audio signals.

For example, the support structure 2964 may be caused to rotate through a plurality of different angular positions, and data from the microphone sensor 2938 may be collected at each such angular position. If such rotational scanning is done while an acoustic event is occurring, the angular position at which the highest acoustic signal strength for that acoustic event is detected will generally indicate the direction along which the acoustic event is occurring. For example, a radius extending from the rotational center of the support structure 2964 through the microphone sensor 2938 may be aligned with the origin of the acoustic event when the support structure 2964 is oriented such that the acoustic signal detected by the microphone sensor 2938 is at a maximum.

In the techniques discussed above in which microphone sensors are used to directionally locate the origin of an acoustic signal, it may be necessary to obtain such sound measurements while the chamber in which the measurements are being taken is held at an atmosphere sufficient to transmit sound waves without experiencing undesirable acoustic signal attenuation. Thus, for example, the process chamber (or other chamber) in which such measurements are to be taken may be controlled so as to cause a gas, e.g., a chemically inert or non-reactive gas such as Argon or Nitrogen, to flow into the chamber in order to provide a sound propagation medium.

In some implementations, sensor-equipped wafers with one or more microphone sensors may be used to determine the origin of acoustic events using, for example, acoustic fingerprinting techniques. For example, as mentioned earlier, acoustic data collected by a microphone sensor may be analyzed to obtain the power spectral density of the acoustic signal. Such power spectral density data may be provided to a machine learning algorithm that classifies the obtained power spectral density into one of several potential acoustic event types or sources based on the characteristics of the power spectral density data. For example, a particular acoustic signal may, after being converted into the frequency domain and analyzed to obtain the power spectral density, exhibit characteristics that align with an acoustic fingerprint in which the three highest signal strengths occur within frequency bands of 100 Hz, 120 Hz, and 200 Hz (each ±5 Hz) and in which the signal strengths of the 120 Hz and 200 Hz frequency components are at 50%±20% of the signal strength of the 100 Hz frequency component.

Such a machine learning algorithm may, for example, be trained using acoustic signal data obtained by such sensor-equipped wafers under conditions in which acoustic events arising from known error or operational conditions are generated. For example, such a machine learning algorithm, e.g., a neural net, may be trained using datasets of acoustic signal data obtained by a sensor-equipped wafer having a microphone sensor while the sensor-equipped wafer is being transported by one or more wafer-handling robots known to produce acoustic events caused by, for example, rotational bearings that are nearing the end of their service life. Different datasets of acoustic signal data arising from different potential acoustic signal sources (error conditions) may be provided to the machine learning algorithm in order to train the algorithm to recognize a variety of different acoustic signal types, each acoustic signal type acting as a fingerprint of a particular error condition that generates such an acoustic signal type. When a particular potential source/error condition associated with a particular acoustic fingerprint is identified, a notification may be generated to inform an operator of a potential error condition.

Acoustic fingerprinting techniques such as are described above may allow for the location of a particular acoustic event to be determined without necessarily needing to rely on multiple microphone sensors or movable microphone sensors, e.g., if an acoustic fingerprint is associated with a particular component in the semiconductor processing tool. This allows a sensor-equipped wafer to, for example, collect acoustic signal data under vacuum conditions and still identify where an acoustic event is likely occurring. For example, acoustic signals may be provided to the sensor-equipped wafer 2900 through acoustic coupling through solid structures, e.g., through the structure of a wafer-handling robot itself. By analyzing the received acoustic signal and matching the frequency component strengths therein to an acoustic fingerprint, the source (component of the semiconductor processing tool generating the signal) of the acoustic signal may potentially be identified, thereby identifying where the acoustic signal originates from.

Since the sensor-equipped wafers discussed herein are self-powered, e.g., having a battery or other power source, and are configured to be able to communicate, e.g., via a wireless connection, with one or more other devices, such sensor-equipped wafers may offer an extremely flexible architecture for collecting measurements that may be used to qualify, evaluate, characterize, and/or quantify various aspects of semiconductor tool performance. For example, in some implementations, such a sensor-equipped wafer may be configured to receive commands indicating that one or more measurements from one or more sensors of that sensor-equipped wafer are to be taken. A controller, e.g., a tool controller that may control various systems of a semiconductor processing tool, that is separate from the sensor-equipped wafer may be configured to establish a communications link with the sensor-equipped wafer and to then periodically send instructions to the sensor-equipped wafer to cause the sensor-equipped wafer to obtain a desired set of measurements For example, the controller may be provided with computer-executable instructions that cause the controller to cause a wafer handling robot of the semiconductor processing tool to retrieve the sensor-equipped wafer, e.g., from a dedicated storage alcove in the EFEM or from a FOUP in which the sensor-equipped wafer is stored, and to move it to one or more locations within the EFEM (and/or buffer and/or FOUP(s)). Such instructions may also cause the controller to send instructions to the sensor-equipped wafer in between moving the sensor-equipped wafer from location to location that cause the sensor-equipped wafer to obtain one or more measurements using one or more of the sensors in the sensor-equipped wafer at each such location.

The measurement data that is collected by such a sensor-equipped wafer may, in some instances, be stored in one or more memory devices on the sensor-equipped wafer and later retrieved. In other, or additional, instances, such measurement data may be transmitted to an external device, e.g., the controller of the semiconductor processing tool in which the sensor-equipped wafer is being used, in real-time or near-real-time using the wireless interface of the sensor-equipped wafer (if present). In the event that the sensor-equipped wafer additionally includes sensors such as relative humidity sensors, temperature sensors, or the like, the sensor readings that are obtained may also include measurement data from such additional sensors as well.

In some implementations, a sensor-equipped wafer may include both airflow sensors and gas concentration and/or partial pressure sensors for use in atmospheric or near-atmospheric conditions. For example, some EFEMs may be configured to have an internal atmosphere within the EFEM that has a different gas composition than may be found in ambient atmospheric air. For example, such an EFEM may be configured to maintain an atmosphere of pure nitrogen (or at least an atmosphere in which oxygen is not present). In actual practice, maintaining such an environment is not possible due to the fact that EFEMs are typically not hermetically sealed (unlike semiconductor processing chambers, which are sealed so as to be able to be kept at a sub-atmospheric pressure, e.g., vacuum). There will thus typically be at least some ambient atmospheric air (with oxygen) that leaks into such EFEMs. Accordingly, it may be desirable to quantify just how much oxygen is leaking into such an EFEM-if within an acceptable limit, then the EFEM may be deemed to have an internal atmosphere that is sufficiently free of oxygen that wafers passed therethrough will not be at risk of unacceptable contamination. If the oxygen levels within the EFEM exceed such a threshold, however, then the semiconductor processing tool controller may generate an error condition that alerts the operator as to a potentially unacceptable rate of oxygen leakage into the EFEM.

In such systems, one or more small, surface-mount gas sensors, e.g., oxygen sensor(s), may be included in the sensor-equipped wafer in addition to (or in place of) the airflow sensor(s). For example, low-profile side-mounted gas sensors, e.g., oxygen sensors, such as are commonly used in medical or safety devices may be used. Such sensors may be electrochemical devices that consume a fuel, e.g., oxygen, to produce an electrical output via chemical reaction and may have a packaging height that is less than 7 mm in thickness in some cases, making them suitable for use in sensor-equipped wafers. Such a sensor package may, for example, be modified to be somewhat thinner in order to achieve a total maximum thickness for the sensor-equipped wafer that is within, for example, 5 mm, or may be used as-is, with the total thickness for the sensor-equipped wafer being greater than, for example, 5 mm. For sensor-equipped wafers that are designed for use within an EFEM, for example, the height limitations may be somewhat relaxed as compared to sensor-equipped wafers that are configured for use within the interior of a semiconductor processing chamber. Thus, a slightly larger maximum thickness of the sensor-equipped wafer, e.g., 6 mm to 8 mm, may be permissible for sensor-equipped wafers that may not need to be delivered into the interior of the semiconductor processing chamber.

The controller 2674 (or the controller 2574) may be further configured to analyze the collected data from the ambient atmospheric (or other) sensors on the sensor-equipped wafer and to determine if the ambient atmospheric conditions within the portions of the semiconductor processing tool for which measurements were taken using the sensor-equipped wafer meet a minimum required threshold or threshold(s). If not, then the controller may cause an error condition to be reported and may, for example, prevent operation of the semiconductor processing tool, or at least a relevant portion thereof, until after a subsequent set of sensor-wafer measurements indicates that the issue has been resolved or until an operator provides, for example, an override command.

It will be appreciated that while the example sensor-equipped wafers discussed above tended to each focus on a sensor-equipped wafer including only a single type of sensor, e.g., one or more upward-facing optical sensors, one or more radially outward-facing optical sensors, one or more ambient atmospheric sensors, etc., sensor-equipped wafers may also be configured to include multiple different types of sensors, e.g., ambient atmospheric sensors and upward-facing and/or radially outward-facing optical sensors. Additionally, some sensor-equipped wafers may further include one or more of: one or more accelerometers, one or more proximity sensors, one or more relative humidity sensors, one or more temperature sensors, one or more sound sensors, etc.

It will also be appreciated that sensor-equipped wafers as discussed herein may feature sensors mounted to the top surface of the substrate (or other structures supported by the substrate), sensors mounted to the underside of the substrate, sensors mounted in the interior of the substrate, sensors mounted near the outer periphery of the substrate, and/or sensors mounted to the edge of the substrate.

As noted above, the controllers discussed herein may be part of a system that may include semiconductor processing equipment, including a processing tool or tools, chamber or chambers, platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, as well as various parameters affecting semiconductor processing, such as the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

In addition to the semiconductor processing tool controller, the sensor-equipped wafers discussed herein may also include a controller that is configured to cause data to be collected from the one or more sensors on the sensor-equipped wafer and to communicate, for example, with the controller of a semiconductor processing tool (or another external controller) in order to receive commands from and/or send data to the semiconductor processing tool.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular measurement operation or calibration operation using a sensor-equipped wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of measurement or calibration operations using a sensor-equipped wafer, examine a history of past measurement or calibration operations using a sensor-equipped wafer, examine trends or performance metrics from a plurality of sensor-equipped wafer measurements of different semiconductor processing tools, etc. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the measurement or calibration steps to be performed during one or more sensor-equipped wafer operations. It should be understood that the parameters may be specific to the type of measurements to be performed and the type of sensor-equipped wafer that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, sensor-equipped wafers may be used in example systems that may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the sensor-equipped wafer and/or tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory. For example, the controller may communicate with a remote system that may dispatch a sensor-equipped wafer to a particular tool, e.g., via a FOUP, in order to allow the sensor-equipped wafer to be used within that tool to obtain measurements or data concerning various aspects of the tool.

It will be appreciated that the techniques discussed herein involving the use of sensor-equipped wafers may be practiced by way of one or more controllers, e.g., the controller located on the sensor-equipped wafer itself or, in many cases, the controller located on the sensor-equipped wafer itself in conjunction with a separate controller, e.g., a controller that is associated with the semiconductor processing tool. Such controllers may, in aggregate or collectively, be configured to perform the techniques discussed herein.

In recognition of the possibility of such distributed processing arrangements, the term “collectively,” as used herein with reference to memory devices and/or processors or various other items, should be understood to indicate that the referenced collection of items has the characteristics or provides the functionalities that are associated with that collection. For example, if a server and a client device collectively store instructions for causing A, B, and C to occur, this encompasses at least the following scenarios:
a) The server stores instructions for causing A, B, and C to occur, but the client device stores no instructions that cause A, B, and C to occur.
b) The client device stores instructions for causing A, B, and C to occur, but the server stores no instructions that cause A, B, and C to occur.
c) The server stores instructions for causing a proper subset of A, B, and C to occur, e.g., A and B but not C, and the client device stores instructions that cause a different proper subset of A, B, and C to occur, e.g., C but not A and B, where instructions for causing each of A, B, and C to occur are respectively stored on either or both the client device and the server.
d) The server stores instructions for causing a subset of A, B, and C to occur, e.g., A and B but not C, and the client device stores instructions that cause a different subset of A, B, and C to occur, e.g., B and C but not A, where instructions for causing each of A, B, and C to occur are respectively stored on either or both the client device and the server.
e) The server stores instructions for causing A and a portion of B to occur, and the client device stores instructions that cause C and the remaining portion of B to occur.

In all of the above scenarios, between the server and the client device, there are, collectively, instructions that are stored for causing A, B, and C to occur, i.e., such instructions are stored on one or both devices and it will be recognized that using the term “collectively,” e.g., the server and the client device, collectively, store instructions for causing A, B, and C to occur, encompasses all of the above scenarios as well as additional, similar scenarios.

Similarly, a collection of processors, e.g., a first set of one or more processors and a second set of one or more processors, may be caused, collectively, to, perform one or more actions, e.g., actions A, B, and C. As with the previous example, various permutations fall within the scope of such “collective” language:
a) The first set of one or more processors may be caused to perform each of A, B, and C, and the second set of one or more processors may not perform any of A, B, or C.
b) The second set of one or more processors may be caused to perform each of A, B, and C, and the first set of one or more processors may not perform any of A, B, or C.
c) The first set of one or more processors may be caused to perform a proper subset of A, B, and C, and the second set of one or more processors may be caused to perform a different proper subset of A, B, and C to be performed such that between the two sets of processors, all of A, B, and C are caused to be performed.
d) The first set of one or more processors may be caused to perform A and a portion of B, and the second set of one or more processors may be caused to perform C and the remainder of B.

The term “wafer,” as used herein, may refer to semiconductor wafers or substrates or other similar types of wafers or substrates; in the context of a sensor-equipped wafer, a wafer may also be made of other materials, e.g., carbon fiber.

It is also to be understood that the use of ordinal indicators, e.g., (a), (b), (c), . . . , herein is for organizational purposes only, and is not intended to convey any particular sequence or importance to the items associated with each ordinal indicator. For example, “(a) obtain information regarding velocity and (b) obtain information regarding position” would be inclusive of obtaining information regarding position before obtaining information regarding velocity, obtaining information regarding velocity before obtaining information regarding position, and obtaining information regarding position simultaneously with obtaining information regarding velocity. There may nonetheless be instances in which some items associated with ordinal indicators may inherently require a particular sequence, e.g., “(a) obtain information regarding velocity, (b) determine a first acceleration based on the information regarding velocity, and (c) obtain information regarding position”; in this example, (a) would need to be performed before (b) since (b) relies on information obtained in (a)-(c), however, could be performed before or after either of (a) or (b).

It is to be understood that use of the word “each,” such as in the phrase “for each <item> of the one or more <items>” or “of each <item>,” if used herein, should be understood to be inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, when a selected item may have one or more sub-items and a selection of one of those sub-items is made, it will be understood that in the case where the selected item has one and only one sub-item, selection of that one sub-item is inherent in the selection of the item itself.

It will also be understood that references to multiple controllers that are configured, in aggregate, to perform various functions are intended to encompass situations in which only one of the controllers is configured to perform all of the functions disclosed or discussed, as well as situations in which the various controllers each perform sub-portions of the functionality discussed. For example, a sensor-equipped wafer may include a controller that is configured to control the operation of the various sensors on the sensor-equipped wafer and communicate data therefrom to another controller associated with a semiconductor processing tool; the semiconductor processing tool controller may then analyze such data to determine various operational parameters regarding the semiconductor processing tool.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Certain features that are described in this specification in the context of separate implementations also can be implemented in combination in a single implementation. Conversely, various features that are described in the context of a single implementation also can be implemented in multiple implementations separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

1. A device for evaluating characteristics of a semiconductor processing tool or component, the device comprising:
a base structure sized so as to be insertable through an opening of the semiconductor processing tool sized to receive wafers for processing and transportable by an object transfer apparatus of the semiconductor processing tool between at least two locations in the semiconductor processing tool, the base structure having a first side configured to contact, and be supported by, a portion of the object transfer apparatus and a second side facing in a direction opposite the first side;
one or more optical sensors, each optical sensor oriented so as to have an upward-facing field of view when the base structure is oriented with the first side facing downward;
a controller, wherein the controller is communicatively connected with each of the one or more optical sensors; and
a power source configured to provide power to at least the controller.

2. The device of claim 1, wherein at least one of the one or more optical sensors is an imaging sensor.

3. The device of claim 1, wherein at least one of the one or more optical sensors is coupled with a corresponding one or more lenses that provide that optical sensor with a field of view of at least 30°.

4. The device of claim 2, wherein the device has two or more optical sensors, and the two or more optical sensors are distributed across the device so as to have overlapping fields of view with respect to a focal plane parallel to, and located a first distance from, the second side.

5. The device of claim 4, wherein the first distance is between 2 mm and 100 mm.

6. The device of claim 5, wherein a region resulting from an intersection of the focal plane with the fields of view of the optical sensors has a total area that is at least 15% of πd²/4, where d is a nominal wafer diameter of wafers that the semiconductor processing tool is configured to process.

7. The device of claim 2, wherein there is a plurality of optical sensors and at least two of the optical sensors are located at different distances from a center point of the base structure.

8. The device of claim 1, further comprising:
a first support structure rotatably coupled with the base structure; and
a first rotational drive configured to cause the first support structure to rotate about a first rotational axis and relative to the base structure responsive to receipt of one or more first control signals, wherein at least one of the one or more optical sensors is supported, directly or indirectly, by the first support structure and is located at a distance offset from the first rotational axis in a direction perpendicular to the first rotational axis.

9. The device of claim 8, wherein there are multiple optical sensors that are supported, directly or indirectly, by the first support structure and at least two of the optical sensors supported by the first support structure are located at different distances from the first rotational axis.

10. The device of claim 9, wherein the first rotational axis is nominally centered on the base structure.

11. The device of claim 9, wherein the first rotational axis is offset from a center of the base structure.

12. The device of claim 11, further comprising:
a second support structure that is rotatably coupled with the first support structure; and
a second rotational drive configured to cause the second support structure to rotate about a second rotational axis and relative to the first support structure responsive to receipt of one or more second control signals, wherein:
the second support structure is supported by the first support structure,
the at least one of the one or more optical sensors is supported by the second support structure, and
the second rotational axis is offset radially from the first rotational axis.

13. The device of claim 1, wherein the base structure has a maximum dimension that is 50% or less of a nominal wafer diameter of wafers that the semiconductor processing tool is configured to process.

14. The device of claim 1, wherein:
the base structure has a maximum dimension that is 50% or less of 300 mm, and
at least one of the one or more optical sensors is positioned at a location on the base structure that is offset from a center axis of the base structure that is perpendicular to the second side.

15. The device of claim 13, wherein there are a plurality of optical sensors and one of the optical sensors is located proximate the center axis of the base structure.

16. The device of claim 1, further comprising a first optical projection unit configured to project a first illumination pattern along a first axis, wherein:
the first axis is at an oblique angle to the second side,
the first axis intersects with a reference plane that is parallel to, and offset a first distance from, the second side,
the first side is farther from the reference plane than the second side, and
the one or more optical sensors are positioned such that at least some locations where the reference plane and the first illumination pattern intersect are within an aggregate field of view of the one or more optical sensors.

17. The device of claim 16, wherein the first illumination pattern intersects the reference plane along a first line.

18. The device of claim 17, further comprising a second optical projection unit, wherein:
the second optical projection unit is configured to project a second illumination pattern along a second reference plane that is perpendicular to the second side and parallel to the first line along which the first illumination pattern intersects the reference plane, and
the second illumination pattern intersects the reference plane along a second line that is parallel to the first line.

19. The device of claim 16, wherein the first illumination pattern intersects the reference plane at a plurality of discrete locations distributed across the reference plane.

20. The device of claim 1, further comprising an inductive charging coil coupled to the power source.
